(19) United States
(12) Patent Application Publication
(10) Pub. No.: US 2026/0182115 A1
(43) Pub. Date: Jun. 25, 2026

(54) DISPLAY APPARATUS

(71) Applicant: LG Display Co., Ltd., Seoul (KR)

(72) Inventors: JiHyun JUNG, Paju-si (KR); Ruda RHE, Paju-si (KR); Hyangmyoung GWON, Paju-si (KR)

(73) Assignee: LG Display Co., Ltd., Seoul (KR)

(21) Appl. No.: 19/190,435

(22) Filed: Apr. 25, 2025

(30) Foreign Application Priority Data
Dec. 20, 2024 (KR) 10-2024-0193036

(51) Int. Cl. H10H 29/49; G06F 3/041; G06F 3/044; H01L 25/16

(52) U.S. Cl. CPC H10H 29/49; G06F 3/0412; G06F 3/04184; G06F 3/0443; G06F 2203/04107; H10W 90/00

(57) ABSTRACT

There is provided a display apparatus comprising a substrate including a display area and a non-display area, a pixel driving circuits provided in the display area, first electrodes connected to the pixel driving circuit, light emitting devices electrically connected to the first electrodes, and a second electrode connected to the light emitting devices, wherein each of the pixel driving circuits is connected to light emitting devices provided in at least two sub-pixels, the second electrode comprises main cathode electrodes connected to light emitting devices and a shield electrode between the main cathode electrodes and separated from the main cathode electrodes, and each of the light emitting devices is connected to any one of the first electrodes.

### CROSS-REFERENCE TO RELATED APPLICATIONS

This application claims the benefit of the Republic of Ko Patent Application No. 10-2024-0193036 filed on Dec. 20, 2024, which is hereby incorporated by reference in its entirety.

### BACKGROUND

### Technical Field

The present disclosure relates to a display apparatus.

### Description of the Related Art

A display apparatus is applied to various electronic devices such as TVs, mobile phones, laptops, and tablets.

Display apparatuses include an organic light emitting display (OLED) that emits light by itself and a liquid crystal display (LCD) that requires a separate light source.

Recently, a display apparatus including a light emitting diode (LED) has attracted attention as a next-generation display apparatus. The light emitting diode is made of an inorganic material, not an organic material. Accordingly, compared to the liquid crystal display or the organic light emitting display, a display apparatus including the light emitting diode has a faster lighting speed, has excellent luminous efficiency, and can display an image having high luminance.

### BRIEF SUMMARY

The present disclosure relates to a display apparatus incorporating a novel second electrode structure designed to enhance display efficiency, luminance, and power performance. In contrast to conventional designs that use a continuous common cathode across sub-pixels, the present introduces a configuration in which main cathode electrodes (CE2m) are individually disposed in each sub-pixel and are physically separated from one another. Between these electrodes, shield electrodes (CE2s) are strategically positioned to provide electrical isolation and improve signal integrity. This separation enables more precise control of each light emitting device (LED), reduces or minimizes crosstalk between adjacent sub-pixels, and contributes to lower power consumption and higher luminance.

Further, the second electrode structure is designed for dual functionality, serving not only as the cathode for the micro-LEDs but also as part of a touch sensing electrode system. During the display period, cathode voltage is supplied to the main cathode electrodes, while a different shield voltage is applied to the shield electrodes. In a touch sensing period, a touch driving signal is concurrently supplied to both, enabling integrated capacitive sensing without requiring additional structures. This multifunctional design allows for space-efficient integration of display and touch features.

Additionally, the design accounts for manufacturing challenges inherent to micro-LED transfer. Multiple LEDs of the same type can be transferred to each sub-pixel, allowing one to function as a main light emitting device and another as a redundancy. After testing, only a single functional LED is activated, improving production yield and reliability. The entire system is supported by a layered connection and insulation architecture that facilitates reliable operation even in flexible or bendable display regions.

Accordingly, the present disclosure is directed to providing a display apparatus that substantially obviates one or more problems due to limitations and disadvantages of the related art.

An aspect of the present disclosure is directed to providing a display apparatus in which main cathode electrodes provided in sub-pixels adjacent to each other are separated from each other, and accordingly, to provide a display apparatus having high efficiency, high luminance and low power characteristics.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description as well as the appended drawings.

To achieve these and other advantages and in accordance with the purpose of the disclosure, as embodied and broadly described herein, there is provided a display apparatus comprising a substrate including a display area and a non-display area, a pixel driving circuits provided in the display area, first electrodes connected to the pixel driving circuit, light emitting devices electrically connected to the first electrodes, and a second electrode connected to the light emitting devices, wherein each of the pixel driving circuits is connected to light emitting devices provided in at least two sub-pixels, the second electrode comprises main cathode electrodes connected to light emitting devices and a shield electrode between the main cathode electrodes and separated from the main cathode electrodes, and each of the light emitting devices is connected to any one of the first electrodes.

It is to be understood that both the foregoing general description and the following detailed description of the present disclosure are example and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a perspective view illustrating a display apparatus according to an embodiment of the present disclosure;

FIG. 2 is a plan view of a display apparatus according to an embodiment of the present disclosure;

FIG. 3 is an enlarged exemplary diagram of a portion of a display apparatus according to an embodiment of the present disclosure;

FIG. 4 is an exemplary diagram illustrating a structure of a circuit applied to a display apparatus according to an embodiment of the present disclosure;

FIGS. 5 to 7B are plan views of a display panel applied to a display apparatus according to an embodiment of the present disclosure;

FIG. 8A is an exemplary diagram illustrating a cross-sectional surface taken along a line V1-V1′ illustrated in FIG. 3;

FIG. 8B is a cross-sectional view of a light emitting device applied to a display apparatus according to an embodiment of the present disclosure;

FIG. 9A is an exemplary diagram illustrating a cross-sectional surface taken along a line A-A′ illustrated in FIG. 7A;

9B is an exemplary diagram illustrating a cross-sectional surface taken along a line B-B′ illustrated in FIG. 7A;

FIG. 10 is an exemplary diagram illustrating a structure of a touch electrode part applied to a display apparatus according to an embodiment of the present disclosure;

FIG. 11A is an exemplary diagram illustrating structures of a sub-touch electrode and a pixel driving circuit applied to a display apparatus according to an embodiment of the present disclosure;

FIG. 11B is an exemplary diagram illustrating a connection structure of a sub-touch electrode and a pixel driving circuit applied to a display apparatus according to an embodiment of the present disclosure;

FIG. 11C is an exemplary diagram illustrating a connection relationship between a pixel driving circuit and light emitting devices applied to a display apparatus according to an embodiment of the present disclosure;

FIG. 11D is an exemplary diagram illustrating a light emitting signal EM applied to a display apparatus according to an embodiment of the present disclosure;

FIG. 11E is an exemplary diagram illustrating a pixel circuit PC applied to a display apparatus according to an embodiment of the present disclosure;

FIG. 11F is an exemplary diagram illustrating a touch sensing method in a display apparatus according to an embodiment of the present disclosure;

FIG. 11G is an exemplary diagram illustrating one frame period applied to a display apparatus according to an embodiment of the present disclosure; and

FIGS. 12 to 15 are diagrams illustrating electronic devices to which a display apparatus according to embodiments of the present disclosure is applied.

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like parts.

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted. When “comprise,” “have,” and “include” described in the present disclosure are used, another part can be added unless “only” is used. The terms of a singular form can include plural forms unless referred to the contrary.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc., can be used herein to describe various elements, these elements should not be limited by these terms. These terms are only used to distinguish one element from another and may not define order of sequence. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc., can be used. These terms are intended to identify the corresponding elements from the other elements, and basis, order, or number of the corresponding elements should not be limited by these terms. The expression that an element is “connected,” “coupled,” or “adhered” to another element or layer should be understood the element or layer cannot only be directly connected or adhered to another element or layer, but also be indirectly connected or adhered to another element or layer with one or more intervening elements or layers “disposed,” or “interposed” between the elements or layers, unless otherwise specified.

As used herein, the term “connected” is intended to have the broadest possible meaning. Specifically, the phrase “A is connected to B” encompasses both a direct connection where no intervening components or elements are present- and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. Also, the term “can” used herein includes all meanings and definitions of the word “may”.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship.

Hereinafter, embodiments of the present disclosure will be described in detail with reference to the accompanying drawings.

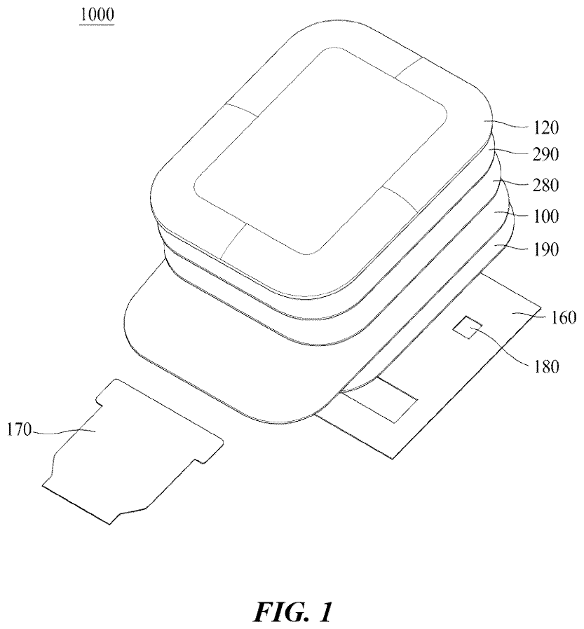

FIG. 1 is a perspective view illustrating a display apparatus according to an embodiment of the present disclosure.

Referring to FIG. 1, a display apparatus 1000 according to an embodiment of the present disclosure can include a display panel 100, a polarizing layer 280, an adhesive layer 290, a cover member 120, a support substrate 190, a flexible circuit board 170, and a printed circuit board 160.

The display panel 100 can display information and an image to be provided to a user.

The polarizing layer 280 can be disposed on the display panel 100. The polarizing layer 280 can prevent or reduce light generated from an external light source from entering the display panel 100 to affect a light emitting device or the like.

The adhesive layer 290 can attach the cover member 120 to the display panel 100. The adhesive layer 290 can be disposed between the polarizing layer 280 and the cover member 120 to attach the cover member 120 to the polarizing layer 280.

The cover member 120 can be disposed on the polarizing layer 280. The cover member 120 can be disposed on the adhesive layer 290. The cover member 120 can be a member for protecting the display panel 100. The cover member 120 can be formed of a transparent material.

The support substrate 190 can be disposed between the display panel 100 and the printed circuit board 160. The support substrate 190 can reinforce rigidity of the display panel 100. The support substrate 190 can be a back plate.

The flexible circuit board 170 and the printed circuit board 160 can be disposed on a bottom of the display panel 100. The flexible circuit board 170 and the printed circuit board 160 can be disposed on one edge of the display panel 100. One side of the flexible circuit board 170 can be attached to the display panel 100 and the other side of the flexible circuit board 170 can be attached to the printed circuit board 160. The flexible circuit board 170 can be a flexible film, but embodiments of the present disclosure are not limited thereto.

The printed circuit board 160 can include at least one hole 180. An internal component that senses ambient light or temperature can be disposed in an area corresponding to at least one hole 180. For example, the internal component can include at least one of an ambient light sensor (ALS) and a temperature sensor.

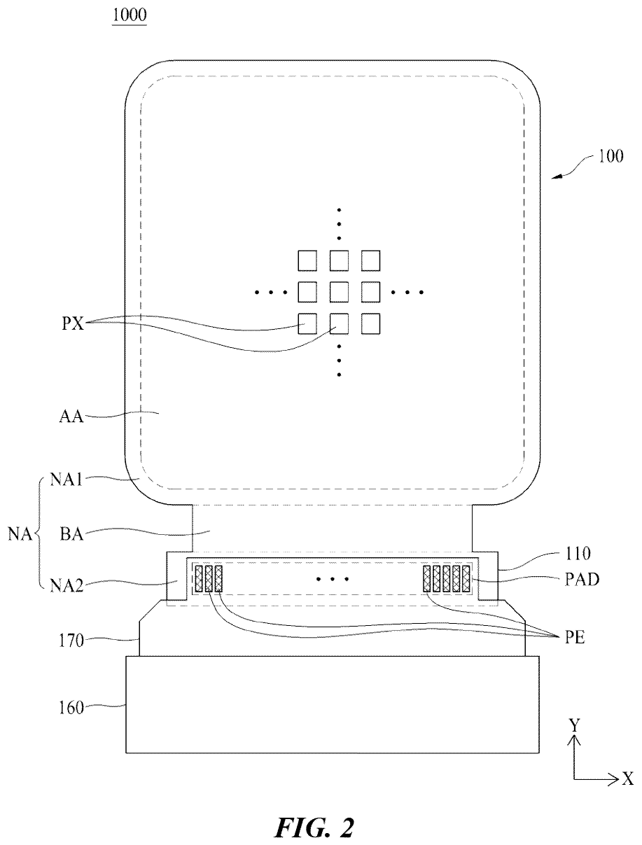

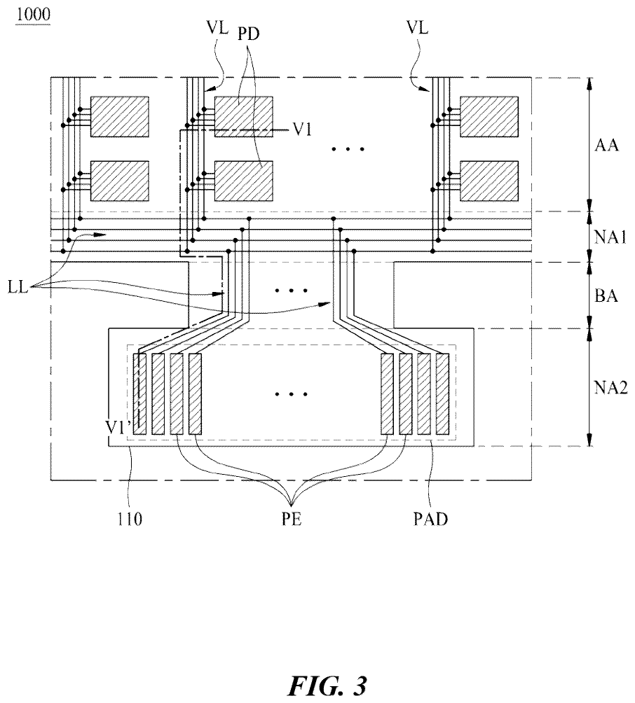

FIG. 2 is a plan view of a display apparatus according to an embodiment of the present disclosure and FIG. 3 is an enlarged exemplary diagram of a portion of a display apparatus according to an embodiment of the present disclosure.

Referring to FIGS. 2 and 3, the display apparatus 1000 can include the display panel 100, the flexible circuit board 170, and the printed circuit board 160.

The display panel 100 can include a substrate 110. The substrate 110 can be a member that supports other components of the display apparatus 1000. The substrate 110 can be made of an insulating material. For example, the substrate 110 can be made of glass or resin. Also, the substrate 110 can be made of a material having flexibility. For example, the substrate 110 can be made of a plastic material having flexibility, such as polyimide (PI).

For example, the display panel 100 can include a display area AA and a non-display area NA. Therefore, the substrate 110 can include the display area AA and the non-display area NA. The display area AA and the non-display area NA can be applied not only to the description of the substrate 110, but also to the description of the display apparatus 1000.

The display area AA can be an area in which an image is displayed. The display area AA can include a plurality of pixels PX. Each of the plurality of pixels PX can include a plurality of sub-pixels. At least one sub-pixel can be disposed in each of the plurality of sub-pixels.

A type of the light emitting device can be variously changed based on a type of the display apparatus 1000. For example, when the display apparatus 1000 is an inorganic light emitting display apparatus, the light emitting device can be a light-emitting diode (LED), a micro light-emitting diode (Micro-LED), or a mini-light-emitting diode (M LED).

The display area AA can be configured in various shapes according to a design of the display apparatus 1000. For example, the display area AA can be configured in a rectangular shape having four rounded corners. For another example, the display area AA can be configured in a rectangular having four corners, each of which has a right-angle shape, or a circular shape.

Referring to FIG. 3, a plurality of pixel driving circuits PD can be disposed in the display area AA. The plurality of pixel driving circuits PD can be circuits for driving light emitting devices provided in the plurality of sub-pixels.

Each of the plurality of pixel driving circuits PD can include a storage capacitor and a plurality of transistors including a driving transistor. In addition, each of the plurality of pixel driving circuits PD can control a light emitting operation of the plurality of light emitting devices by supplying a control signal, a power source, and a driving current to the light emitting devices provided in the plurality of sub-pixels. For example, the pixel driving circuit PD can include a power line and a signal line for controlling light emission on/off and/or light emission time of the light emitting device. For example, the plurality of pixel driving circuits PD can be manufactured using a metal-oxide-silicon field effect transistor (MOSFET) manufacturing process on a semiconductor substrate.

The non-display area NA can be an area in which no image is displayed. Various lines, circuits, and the like for driving the plurality of pixels PX of the display area AA can be disposed in the non-display area NA. For example, various lines and driving circuits can be mounted in the non-display area NA. Also, a pad part PAD to which an integrated circuit, a printed circuit, and the like is connected can be disposed in the non-display area NA.

For example, the driving circuit can be a data driving circuit and/or a gate driving circuit. Lines to which a control signal for controlling the driving circuits is supplied can be disposed in the non-display area NA. For example, the control signal can include a clock signal, an input data enable signal, and synchronization signals. The control signal can be received through the pad part PAD. For example, link lines LL for transmitting a signal can be disposed in the non-display area NA. For example, a driving component such as the flexible circuit board 170 and the printed circuit board 160 can be connected to the pad part PAD.

According to the present disclosure, the non-display area NA can include a first non-display area NA1, a bending area BA, and a second non-display area NA2.

For example, the first non-display area NA1 can be an area surrounding at least a portion of the display area AA.

The bending area BA can be an area extending from at least one of a plurality of sides of the first non-display area NA1 and can be a bendable area.

The second non-display area NA2 is an area extending from the bending area BA, and the pad part PAD can be disposed in the second non-display area NA2.

For example, the bending area BA can be bent, and a remaining area of the substrate 110 except for the bending area BA can be flat. In this case, as the bending area BA is bent, the second non-display area NA2 can be disposed on a rear surface of the display area AA.

A plurality of link lines LL can be disposed in the non-display area NA. The plurality of link lines LL can be lines for transmitting various signals from one or more flexible circuit boards (or flexible films) 170 and the printed circuit board 160 to the display area AA. The plurality of link lines LL can extend from a plurality of pad electrodes PE of the second non-display area NA2 toward the bending area BA and the first non-display area NA1 to be electrically connected to a plurality of driving lines VL of the display area AA.

The plurality of pixel driving circuits PD can be driven by signals transmitted from one or more flexible circuit boards (or flexible films) 170 and the printed circuit board 160 through the driving line VL in the display area AA and the link line LL in the non-display area NA.

For example, each of the driving line VL and the link line LL can be a line for transmitting a signal output from the flexible circuit board (or flexible film) 170 and the printed circuit board 160 to the pixel driving circuit PD. The driving line VL can be disposed in the display area AA to be electrically connected to the pixel driving circuit PD. The driving line VL can extend from the display area AA toward the non-display area NA to be electrically connected to the link line LL. Accordingly, the signal output from the flexible circuit board (or flexible film) 170 and the printed circuit board 160 can be transmitted to the pixel driving circuit PD through the link line LL and the driving line VL.

As the bending area BA is bent, a portion of the link line LL can also be bent with the bending area BA. Stress is concentrated on a portion of the bent link line LL, and thus, a crack can occur in the link line LL. The link line LL can be formed of a conductive material having excellent ductility in order to reduce cracks when the bending area BA is bent.

The link line LL can be configured in various shapes to reduce stress. At least a portion of the link line LL disposed on the bending area BA can extend in a same direction as the extending direction of the bending area BA, or can extend in a direction different from the extending direction of the bending area BA to reduce stress. For example, when the bending area BA extends in one direction from the first non-display area NA1 to the second non-display area NA2, at least a portion of the link line LL disposed on the bending area BA can extend in a direction inclined to the one direction.

For another example, at least a portion of the link line LL can be formed in various shapes of patterns. For example, at least a portion of the link line LL disposed on the bending area BA can have a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged.

Therefore, in order to minimize the stress concentrated on the link line LL and the crack due to the stress, the shape of the link line LL can be formed in various shapes including the above-described shape.

According to the present disclosure, a width of the second non-display area NA2 in which the plurality of pad electrodes PE is disposed can be wider than a width of the bending area BA in which only the plurality of link lines LL is disposed. Also, a width of the display area AA in which the plurality of sub-pixels is disposed can be wider than the width of the bending area BA in which only the plurality of link line LL is disposed. A substrate 110 in which a width of the bending area BA is narrower than a width of other areas of the substrate 110 is shown in FIGS. 2 and 3. However, a shape of the substrate 110 including the bending area BA is exemplary, and thus, embodiments of the present disclosure are not limited thereto.

A pad part PAD including the plurality of pad electrodes PE can be disposed in the second non-display area NA2. A driving component including one or more the flexible circuit boards (or flexible films) 170 and the printed circuit board 160 can be attached to or bonded to the pad part PAD. The plurality of pad electrodes PE are electrically connected to one or more flexible circuit boards (or flexible films), and can transmit various signals (or power) received from the printed circuit board 160 and the flexible circuit board (or flexible film) 170 to the plurality of pixel driving circuits PD in the display area AA.

The flexible circuit board (or flexible film) 170 can be a film having a flexibility and various components can be disposed on the flexible circuit board. For example, a driving IC such as a gate driver IC or a data driver IC can be disposed on the flexible circuit board (or flexible film). In the following description, the driving IC can be referred to as a driving driver.

The driving IC can be a component that processes data and a driving signal for displaying an image.

The printed circuit board 160 can be electrically connected to one or more flexible circuit boards (or flexible films) 170, and supply signals to the driving IC. The printed circuit board 160 can be disposed on one side of the flexible circuit board (or flexible film) 170 to be electrically connected to the flexible circuit board (or flexible film). Various components for supplying various signals to the driving IC can be disposed on the printed circuit board 160. For example, various components, such as a timing controller, a power supply part, a memory, a processor, etc., can be disposed on the printed circuit board 160. For example, the printed circuit board 160 can include a power management integrated circuit (PMIC).

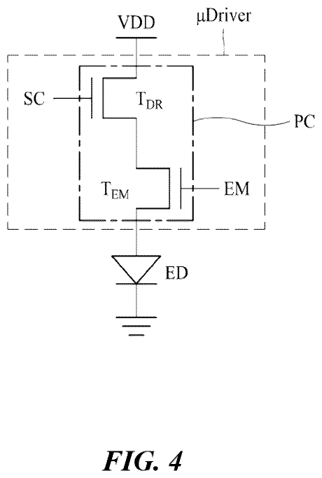

FIG. 4 is an exemplary diagram illustrating a structure of a circuit applied to a display apparatus according to an embodiment of the present disclosure.

The pixel driving circuit PD described with reference to FIG. 3 can be a micro-driver (μDriver) illustrated in FIG. 4. FIG. 4 illustrates that one light emitting device ED is connected to one micro-driver (μDriver), but is not limited thereto.

For example, eight light emitting devices ED can be connected to one micro-driver (μDriver). For another example, 16 light emitting devices ED can be connected to one micro-driver (μDriver) and 32 light emitting devices ED or 64 light emitting devices ED can be connected to one micro-driver (μDriver). The light emitting device ED can be a micro light emitting device (μLED). In addition, one pixel driving circuit PD (eg., micro-driver (μDriver)) can be connected to at least two light emitting devices ED. In this case, one pixel driving circuit PD (e.g., micro-driver (μDriver)) can include one or more pixel driving circuits PC illustrated in FIG. 4. The pixel circuit PC can be connected to at least one light emitting device ED.

The pixel driving circuit PC included in the micro driver μDriver can include a driving transistor TDR and a light emitting transistor TEM.

For example, a high potential power voltage VDD can be applied to a first electrode of the driving transistor TDR, a first electrode of the light emitting transistor TEM can be connected to a second electrode of the driving transistor TDR, and a scan signal SC can be applied to a gate electrode of the driving transistor TDR. The scan signal SC applied to the gate electrode of the driving transistor TDR can be a direct current power source, and a fixed reference voltage can be applied in every frame.

The second electrode of the driving transistor TDR can be connected to a first electrode of the light emitting transistor TEM, the light emitting device ED can be connected to a second electrode of the light emitting transistor TEM, and a light emitting signal EM can be applied to a gate electrode of the light emitting transistor TEM. The light emitting signal EM applied to the gate electrode of the light emitting transistor TEM can be a pulse width modulation signal (PWM) that changes in every frame.

A first electrode of the light emitting device ED can be connected to the second electrode of the light emitting transistor TEM, and a second electrode of the light emitting device ED can be connected to ground. For example, the first electrode of the light emitting device ED can be an anode electrode and the second electrode of the light emitting device ED can be a cathode electrode.

Each of the driving transistor TDR and the light emitting transistor TEM can be an n-type transistor or a p-type transistor.

The driving transistor TDR can be turned on by the scan signal SC applied from a timing controller T-CON and the light emitting transistor TEM can be turned on by the light emitting signal EM. In this case, a driving current can be applied to the light emitting device ED through the driving transistor TDR and the light emitting transistor TEM by the high potential power voltage VDD applied to the first electrode of the driving transistor TDR, and thus the light emitting device ED can emit light.

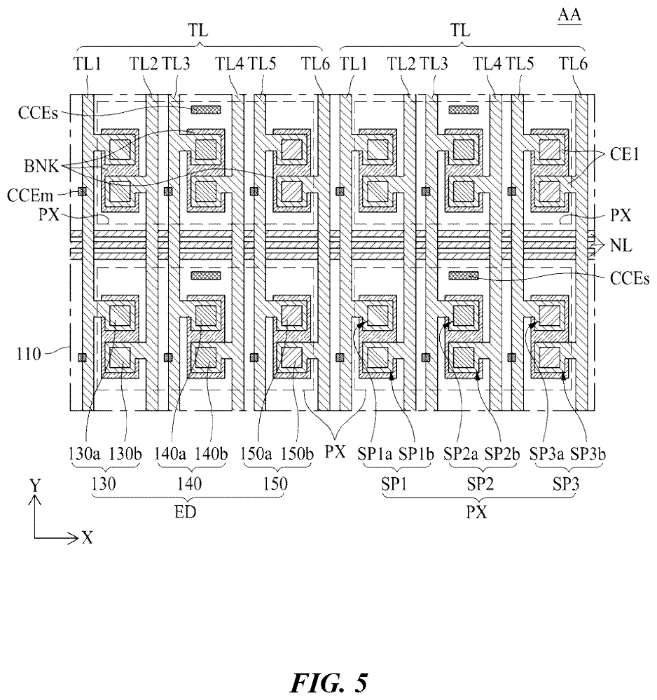

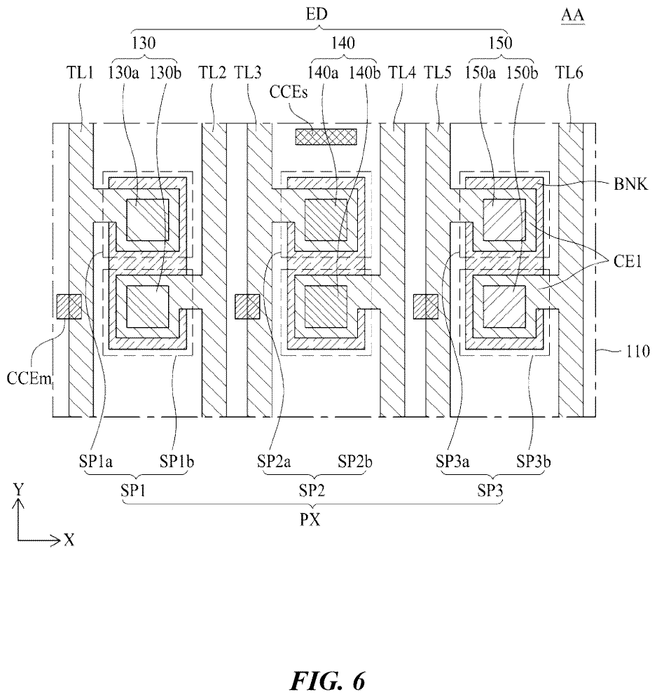

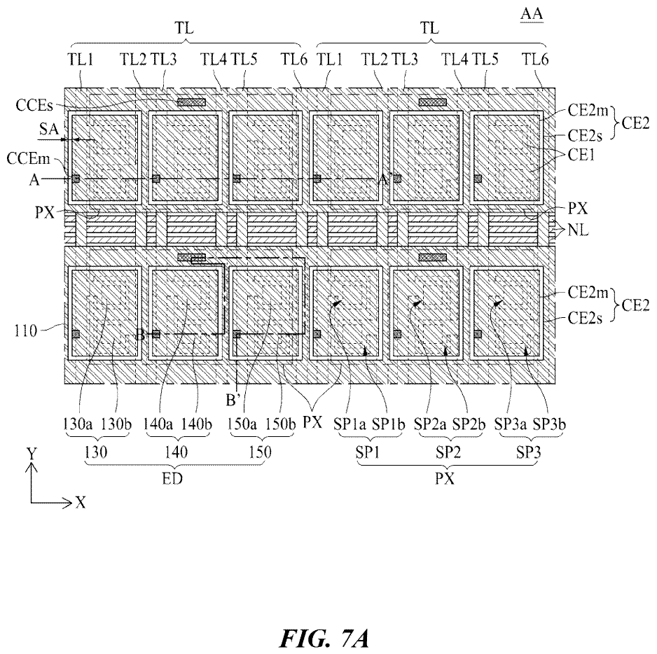

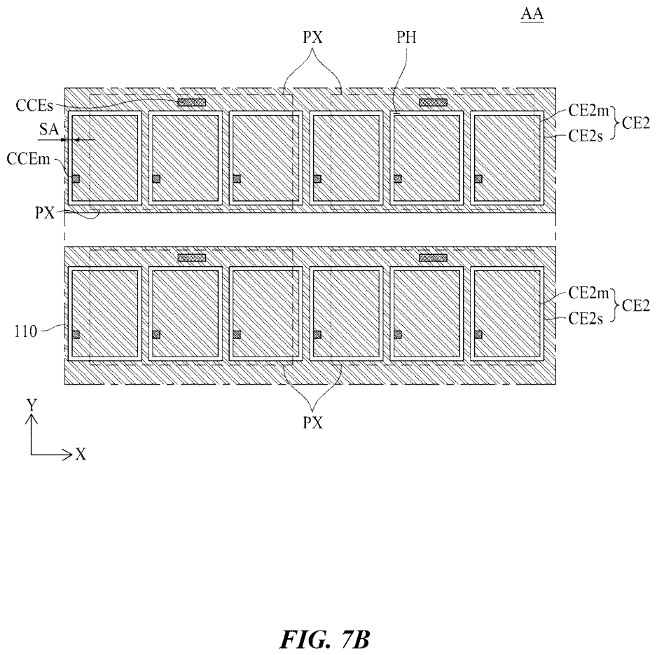

FIGS. 5 to 7B are plan views of a display panel applied to a display apparatus according to an embodiment of the present disclosure. For example, FIG. 5 is an enlarged plan view of a portion of the display area AA including a plurality of pixels, FIG. 6 is an enlarged plan view of the display area AA including one pixel, FIG. 7A is another plan view of the area illustrated in FIG. 5, and FIG. 7B is a plan view illustrating two second electrodes CE2 illustrated in FIG. 7A. A plurality of signal lines TL, a plurality of communication lines NL, a plurality of first electrodes CE1, a plurality of banks BNK, and a plurality of light emitting devices ED are illustrated in FIGS. 5 and 6. FIG. 7A illustrates two second electrodes CE2 added to the plan view illustrated in FIG. 5, and FIG. 7B illustrates two second electrodes CE2 illustrated in FIG. 7A.

Referring to FIGS. 5 to 7B, a plurality of pixels PX including a plurality of sub-pixels can be disposed in the display area AA. Each of the plurality of sub-pixels includes a light emitting device ED and can independently emit light. The plurality of sub-pixels can be configured in a plurality of rows and a plurality of columns and can be disposed in a matrix form.

The plurality of sub-pixels can include a first sub-pixel SP1, a second sub-pixel SP2, and a third sub-pixel SP3. For example, any one of the first sub-pixel SP1, the second sub-pixel SP2, and the third sub-pixel SP3 can be a red sub-pixel, another can be a green sub-pixel, and the other can be a blue sub-pixel. Types of the plurality of sub-pixels are examples, and embodiments of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3.

The pair of first sub-pixels SP1 can include a 1ath sub-pixel SP1a and a 1bth sub-pixel SP1b. The pair of second sub-pixels SP2 can include a 2ath sub-pixel SP2a and a 2bth sub-pixel SP2b. The pair of third sub-pixels SP3 can include a 3ath sub-pixel SP3a and a 3bth sub-pixel SP3b. For example, one pixel PX can include the 1ath sub-pixel SP1a, the 1bth sub-pixel SP1b, the 2ath sub-pixel SP2a, the 2bth sub-pixel SP2b, the 3ath sub-pixel SP3a, and the 3bth sub-pixel SP3b.

The plurality of sub-pixels constituting one pixel PX can be variously arranged. For example, in one pixel PX, the pair of first sub-pixels SP1 can be disposed in the same column, the pair of second sub-pixels SP2 can be disposed in the same column, and the pair of third sub-pixels SP3 can be disposed in the same column. The first sub-pixel SP1, the second sub-pixel SP2, and the third sub-pixel SP3 can be disposed in the same row. The number and arrangement of the plurality of sub-pixels constituting one pixel PX are examples, and embodiments of the present disclosure are not limited thereto.

The plurality of signal lines TL can be disposed in an area between the plurality of sub-pixels. The plurality of signal lines TL can extend in a column direction between the plurality of sub-pixels. The plurality of signal lines TL can be lines that transmit an anode voltage from the pixel driving circuit PD (showed in FIG. 3) to the plurality of sub-pixels. For example, the signal line TL can be electrically connected to the pixel driving circuit PD and the first electrode CE1 of the sub-pixel. The anode voltage output from the pixel driving circuit PD (for example, from the micro-driver (μDriver)) can be transmitted to the first electrode CE1 of the sub-pixel through the signal line TL.

For example, the first electrode CE1 can be an electrode electrically connected to the anode electrode of the light emitting device ED. The anode voltage transmitted through the signal line TL can be transmitted to the anode electrode of the light emitting device ED through the first electrode CE1. That is, the first electrode CE1 is connected to the anode electrode. Accordingly, in the following description, the first electrode CE1 can mean the anode electrode, or can mean a separate electrode connected to the anode electrode.

In the display apparatus according to an example of the present disclosure, instead of forming a plurality of transistors and storage capacitors in each of the plurality of sub-pixels, the pixel driving circuit PD in which the plurality of pixel circuits is integrated is used, and thus, a structure of the display apparatus 1000 can be simplified. In addition, because a circuit disposed in each of the plurality of sub-pixels is integrated in one pixel driving circuit PD, high efficiency and low power driving can be possible.

The plurality of signal lines TL can include a first signal line TL1, a second signal line TL2, a third signal line TL3, a fourth signal line TL4, a fifth signal line TL5, and a sixth signal line TL6. Each of the first signal line TL1 and the second signal line TL2 can be electrically connected to the pair of first sub-pixels SP1. Each of the third signal line TL3 and the fourth signal line TL4 can be electrically connected to the pair of second sub-pixels SP2. Each of the fifth signal line TL5 and the sixth signal line TL6 can be electrically connected to the pair of third sub-pixels SP3.

The first signal line TL1 can be disposed at one side of the pair of first sub-pixels SP1, and the second signal line TL2 can be disposed at the other side of the pair of first sub-pixels SP1. The first signal line TL1 can be electrically connected to one of the pair of first sub-pixels SP1, for example, the first electrode CE1 of the 1ath sub-pixel SP1a. The second signal line TL2 can be electrically connected to the remaining first sub-pixel SP1 of the pair of first sub-pixels SP1, for example, the first electrode CE1 of the 1bth sub-pixel SP1b.

The third signal line TL3 can be disposed at one side of the pair of second sub-pixels SP2, and the fourth signal line TL4 can be disposed at the other side of the pair of second sub-pixels SP2. For example, the third signal line TL3 can be disposed adjacent to the second signal line TL2. The third signal line TL3 can be electrically connected to one of the pair of second sub-pixels SP2, for example, the first electrode CE1 of the 2ath sub-pixel SP2a. The fourth signal line TL4 can be electrically connected to the remaining second sub-pixel SP2 of the pair of second sub-pixels SP2, for example, the first electrode CE1 of the 2bth sub-pixel SP2b.

Also, the fifth signal line TL5 can be disposed at one side of the pair of third sub-pixels SP3, and the sixth signal line TL6 can be disposed at the other side of the pair of third sub-pixels SP3.

The plurality of signal lines TL can further include main cathode electrode lines connected to main cathode electrode CE2m and shield electrode lines connected to shield electrode CE2s. The signal line TL can be formed of a conductive material. For example, the signal line TL can be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. For another example, the plurality of signal lines TL can be formed of a multilayer structure including conductive materials. For example, the plurality of signal lines TL can be formed of the multilayer structure in which titanium (Ti), aluminum (Al), titanium (Ti), and indium tin oxide (ITO) are stacked.

The plurality of communication lines NL can be disposed in an area between adjacent pixels PX. The communication line NL can be disposed to extend in a row direction in an area between the adjacent pixels PX. The communication line NL can be disposed in an area between adjacent electrodes CE2 and may not overlap the adjacent second electrodes CE2. For example, the communication line NL can be a line used for short-range communication such as near field communication (NFC). The communication line NL can function as an antenna.

According to the present disclosure, a bank BNK can be disposed in each of the plurality of sub-pixels. The bank BNK can be a structure in which the plurality of light emitting devices ED is disposed. The plurality of banks BNK can guide positions of the plurality of light emitting devices ED in a transfer process of the plurality of light emitting devices ED. The plurality of light emitting devices ED can be transferred onto the plurality of banks BNK in the transfer process of the plurality of light emitting devices ED. The entire area of the light emitting device ED can overlap the bank BNK. The plurality of banks BNK can be bank patterns or construction, but embodiments of the present disclosure are not limited thereto.

A bank BNK of the first sub-pixel SP1, a bank BNK of the second sub-pixel SP2, and a bank BNK of the third sub-pixel SP3 can be disposed to be spaced apart from each other. The bank BNK of the first sub-pixel SP1, the bank BNK of the second sub-pixel SP2, and the bank BNK of the third sub-pixel SP3 can be configured to be separated. Accordingly, the banks BNK of the first sub-pixel SP1, the second sub-pixel SP2, and the third sub-pixel SP3 to which different types of light emitting devices ED are transferred can be easily identified.

The bank BNK of the 1ath sub-pixel SP1a and the bank BNK of the 1bth sub-pixel SP1b can be connected to each other or can be spaced apart from each other. For example, the bank BNK of the last sub-pixel SP1a and the bank BNK of the 1bth sub-pixel SP1b in which the same light emitting device ED is disposed can be connected or can be separated or spaced apart from each other in consideration of design such as transfer process requirements. Also, the bank BNK of the 2ath sub-pixel SP2a and the bank BNK of the 2bth sub-pixel SP2b can be connected to each other or can be separated or spaced apart from each other. The bank BNK of the Bath sub-pixel SP3a and the bank BNK of the 3bth sub-pixel SP3b can be connected to each other or can be separated or spaced apart from each other. Accordingly, the bank BNK of the pair of first sub-pixels SP1, the bank BNK of the pair of second sub-pixels SP2, and the bank BNK of the pair of third sub-pixels SP3 can be variously formed.

For example, each of the plurality of banks BNK can be formed of an organic insulating material. Each of the plurality of banks BNK can be formed of a single layer or a multilayer of an organic insulating material. For example, each of the plurality of banks BNK can be formed of a photo resist, a polyimide (PI), an acryl-based material, or the like.

The first electrode CE1 can be disposed in each of the plurality of sub-pixels. The first electrode CE1 can overlap the bank BNK to be disposed on the bank BNK. The first electrode CE1 can be electrically connected to one of the plurality of signal lines TL.

At least a portion of the first electrode CE1 can extend to an outside of the bank BNK to be electrically connected to the signal line TL closest to the first electrode CE1. A portion of the first electrode CE1 can overlap the bank BNK, and the rest of the first electrode CE1 may not overlap the bank BNK.

For example, a portion of the first electrode CE1 of the 1ath sub-pixel SP1a can extend to one side area of the 1ath sub-pixel SP1a to be electrically connected to the first signal line TL1, and a portion of the first electrode CE1 of the 1bth sub-pixel SP1b can extend to the other side area of the 1bth sub-pixel SP1b to be electrically connected to the second signal line TL2. A portion of the first electrode CE1 of the 2ath sub-pixel SP2a can extend to one side area of the 2ath sub-pixel SP2a to be electrically connected to the third signal line TL3, and a portion of the first electrode CE1 of the 2bth sub-pixel SP2b can extend to the other side area of the 2bth sub-pixel SP2b to be electrically connected to the fourth signal line TL4. A portion of the first electrode CE1 of the 3ath sub-pixel SP3a can extend to one side area of the 3ath sub-pixel SP3a to be electrically connected to the fifth signal line TL5, and a portion of the first electrode CE1 of the 3bth sub-pixel SP3b can extend to the other side area of the 3bth sub-pixel SP3b to be electrically connected to the sixth signal line TL6.

The first electrode CE1 is electrically connected to the anode electrode of the light emitting device ED. The anode voltage from the pixel driving circuit PD can be transmitted to the light emitting device ED via the signal line TL and the first electrode CE1. A different voltage can be applied to the first electrode CE1 of each of the plurality of sub-pixels according to an image that is displayed. For example, different voltage can be applied to the first electrodes CE1 of the plurality of sub-pixels. Accordingly, the first electrode CE1 can be referred to as a pixel electrode.

The first electrode CE1 can be formed of a conductive material. For example, the first electrode CE1 can be formed integrally with the signal line TL. For example, the first electrode CE1 can be formed of the same conductive material as the signal line TL. For example, the first electrode CE1 can be formed of one of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like. For another example, the first electrode CE1 can be formed of a multilayer structure of the conductive material. For example, the plurality of first electrodes CE1 can be formed of the multilayer structure in which titanium (Ti), aluminum (Al), titanium (Ti), and indium tin oxide (ITO) are stacked.

The light emitting device ED can be disposed in each of a plurality of sub-pixels. The plurality of light emitting device ED can be any one of a light-emitting diode (LED) and a micro light-emitting diode (Micro LED). The plurality of light emitting devices ED can overlap the bank BNK and the first electrode CE1 to be disposed on the bank BNK and the first electrode CE1. The entire area of the light emitting device ED can overlap the bank BNK and the first electrode CE1.

The light emitting devices ED can be disposed on the first electrode CE1 and can be electrically connected to the first electrode CE1. Accordingly, the light emitting device ED can emit light by using the anode voltage from the pixel driving circuit PD through the signal line TL and the first electrode CE1.

The plurality of light emitting devices ED can include a first light emitting device 130, a second light emitting device 140, and a third light emitting device 150. The first light emitting device 130 can be disposed in the first sub-pixel SP1. The second light emitting device 140 can be disposed in the second sub-pixel SP2. The third light emitting device 150 can be disposed in the third sub-pixel SP3. For example, one of the first light emitting device 130, the second light emitting device 140, and the third light emitting device 150 can be a red light emitting device, another can be a green light emitting device, and the other can be a blue light emitting device, but embodiments of the present disclosure are not limited thereto. Light of various colors including white can be implemented by combining red light, green light, and blue light emitted from the plurality of light emitting devices ED. Types of the plurality of light emitting devices ED are examples, and embodiments of the present disclosure are not limited thereto.

The first light emitting device 130 can include a 1ath light emitting device 130a disposed in the 1ath sub-pixel SP1a and a 1bth light emitting device 130b disposed in the 1bth sub-pixel SP1b. The second light emitting device 140 can include a 2ath light emitting device 140a disposed in the 2ath sub-pixel SP2a and a 2bth light emitting device 140b disposed in the 2bth sub-pixel SP2b. The third light emitting device 150 can include a 3ath light emitting device 150a disposed in the 3ath sub-pixel SP3a and a 3bth light emitting device 150b disposed in the 3bth sub-pixel SP3b.

The second electrode CE2 can include a main cathode electrode CE2m connected to the light emitting devices ED and a shield electrode CE2s between the main cathode electrodes CE2m and separated from the main cathode electrodes CE2m, as shown in FIGS. 7A and 7B. In this case, the main cathode electrodes CE2m can be spaced apart from each other with the shield electrode CE2s interposed therebetween in a non-overlapping configuration.

The plurality of signal lines TL can further include main cathode electrode lines connected to the main cathode electrode CE2m and shield electrode lines connected to the shield electrode CE2s.

The main cathode electrodes CE2m are connected to the light emitting devices ED, and the shield electrodes CE2s are provided between at least two main cathode electrodes CE2m adjacent to each other.

For example, as shown in FIGS. 7A and 7B, the main cathode electrode CE2m is provided in the form of an island in an area corresponding to a light emitting device ED, and the shield electrode CE2s is provided outside the main cathode electrode CE2m. Two second electrodes CE2 are shown in FIGS. 7A and 7B. Each of the two second electrodes CE2 can include main cathode electrodes CE2m and a shield electrode CE2s.

The shield electrode CE2s can extend in a first direction of the substrate, for example, in an X-axis direction illustrated in FIGS. 7A and 7B. Therefore, in the following description, a reference numeral X can be assigned to the first direction. A through hole PH through which a light emitting device ED is exposed can be provided in a region corresponding to a light emitting device ED in the shield electrode CE2s, and the main cathode electrode CE2m can be provided in the form of an island in the through hole PH.

To provide an additional description, a through hole PH can be provided in the shield electrode CE2s, a main cathode electrode CE2m can be provided in the through hole PH, and a separation area SA in which the main cathode electrode CE2m and the shield electrode CE2s are separated from each other can be provided outside the main cathode electrode CE2m. That is, the separation area SA can be a part of the through hole PH.

In this case, the separation area SA can surround the outside of the main cathode electrode CE2m in a ring shape.

Each of the main cathode electrodes CE2m can be connected to the main cathode electrode line through a main contact electrode CCEm, and the shield electrode CE2s can be connected to a shield electrode line through at least one shield contact electrode CCEs.

The main cathode electrode line and the shield electrode line can be connected to the pixel driving circuit PD.

At least two second electrodes CE2 connected to any one pixel driving circuit PD can be used as one touch electrode. For example, the two second electrodes CE2 shown in FIGS. 7A and 7B can be used as one touch electrode.

In this case, each of the at least two second electrodes CE2 can extend along the first direction X of the substrate 110, and at least two second electrodes CE2 can be provided along the second direction different from the first direction X. The second direction can be a Y-axis direction shown in FIGS. 7A and 7B. Therefore, in the following description, a reference numeral Y can be assigned to the second direction.

When a cathode voltage is supplied to any one of the at least two second electrodes CE2, light can be output from a light emitting devices ED connected to the second electrode CE2 to which the cathode voltage is supplied.

When the at least two second electrodes CE2 are used as one touch electrode, a touch driving signal can be concurrently (or in some embodiments, simultaneously) supplied to the at least two second electrodes CE2.

For example, during a display period in which an image is displayed, a cathode voltage can be supplied from the pixel driving circuit PD to the main cathode electrode CE2m through the main cathode electrode line and the main contact electrode CCEm, and a shield voltage different from the cathode voltage can be supplied from the pixel driving circuit PD to the shield electrode CE2s through the shield electrode line and the shield contact electrode CCEs.

For example, during a touch period in which a touch is sensed, a touch driving signal can be supplied from the pixel driving circuit PD to the main cathode electrode CE2m and the shield electrode CE2s through the main cathode electrode line and the shield electrode line.

The main cathode electrode CE2m can be disposed in each of the plurality of sub-pixels.

The main cathode electrode CE2m can be disposed on the light emitting device ED. The main cathode electrode CE2m can be electrically connected to the pixel driving circuit PD through the main contact electrodes CCEm and the main cathode electrode line.

For example, the main cathode electrode CE2m can be electrically connected to the cathode electrode of the light emitting device ED to transmit the cathode voltage from the pixel driving circuit PD to the cathode electrode of the light emitting device ED. That is, the main cathode electrode CE2m is connected to the cathode electrode. Therefore, in the following description, the main cathode electrode CE2m can refer to a cathode electrode or a separate electrode connected to the cathode electrode.

The same cathode voltage can be applied to the main cathode electrodes CE2m of the plurality of sub-pixels. For example, the same voltage can be applied to the main cathode electrodes CE2m provided in the plurality of sub-pixels. Accordingly, the main cathode electrode CE2m can be referred to as a common electrode.

At least some of the plurality of sub-pixels can share the main cathode electrode CE2m. For example, the main cathode electrode CE2m can be provided in at least two sub-pixels. For example, the main cathode electrode CE2m can be provided in at least one pixel PX among a plurality of pixels PX disposed in the same row in the horizontal direction (X-axis direction). For example, one main cathode electrode CE2m can be disposed in a plurality of pixels PX. Also, one main cathode electrode CE2m can be disposed in a sub-pixel. FIGS. 7A and 7B illustrate a display apparatus in which a main cathode electrode CE2m is provided for each sub-pixel.

As described above, the second electrode CE2 can include the main cathode electrodes CE2m and the shield electrode CE2s. In this case, at least two through holes PH can be provided in the shield electrode CE2s, and the main cathode electrode CE2m can be provided in each of the through holes PH.

At least two second electrodes CE2 can be connected to one pixel driving circuit PD.

In this case, the second electrodes CE2 of the plurality of sub-pixels can be spaced apart from each other or separated from each other. For example, the second electrode CE2 connected to the pixels PX of an n-th row and the second electrode CE2 connected to the pixels PX of an n+1th row can be spaced apart from each other or separated from each other. For example, as illustrated in FIGS. 7a and 7b, the plurality of second electrodes CE2 can be spaced apart from each other with the plurality of communication lines NL extending in a row direction interposed therebetween. Accordingly, the number of the plurality of sub-pixels can be greater than the number of the plurality of second electrodes CE2.

The plurality of second electrodes CE2 can be formed of a transparent conductive material. When the plurality of second electrodes CE2 are formed of the transparent conductive material, light emitted from the light emitting device ED is directed to an upper portion of the second electrode CE2. For example, the second electrode CE2 can be formed of the transparent conductive material such as indium tin oxide (ITO), indium zinc oxide (IZO), indium gallium zinc oxide (IGZO), or the like.

A plurality of main contact electrodes CCEm and a plurality of shield contact electrodes CCEs can be disposed on the substrate 110. Each of the plurality of main cathode electrodes CE2m can overlap at least one main contact electrode CCEm, and each of the plurality of shield contact electrodes CCEs can overlap at least one shield contact electrode CCEs. For example, as illustrated in FIGS. 7A and 7B, one main cathode electrode CE2m can overlap one main contact electrode CCEm, and one shield electrode CE2s can overlap two shield contact electrodes CCEs.

The main contact electrode CCEm can transmit a cathode voltage or a touch driving signal transmitted from the pixel driving circuit PD through the main cathode electrode line to the main cathode electrode CE2m.

The shield contact electrode CCEs can transmit a shield voltage or a touch driving signal transmitted through the shield electrode line from the pixel driving circuit PD to the shield electrode CE2s.

When a micro LED is used as the light emitting device ED, a plurality of micro LEDs can be formed in a wafer and the micro LEDs can be transferred to the substrate 110, and thus the display panel 100 can be manufactured. Various defects can occur in the process of transferring the plurality of light emitting devices ED having a micro size from the wafer to the substrate 110. For example, a non-transmission defect in which the light emitting device ED is not transferred can occur in some sub-pixels, and a defect in which the light emitting device ED is transferred out of a correct position due to an alignment error can occur in some sub-pixels. Also, even if the transfer process has proceeded normally, the transferred light emitting device ED itself can be a defect. Accordingly, the plurality of the same light emitting devices ED can be transferred to one sub-pixel in consideration of the defect during the transfer process of the plurality of light emitting devices ED. After the lighting test of the plurality of light emitting devices ED is performed, only one light emitting device ED finally determined to be normal can be used.

For example, the 1ath light emitting device 130a and the 1bth light emitting device 130b can be transferred to one pixel PX, and it is possible to inspect whether there is a defect in the 1ath light emitting device 130a and the 1bth light emitting device 130b. If both of the 1ath light emitting device 130a and the 1bth light emitting device 130b are determined to be normal, only the 1ath light emitting device 130b can be used and the 1bth light emitting device 130b can be not used. As another example, if only the 1bth light emitting device 130b of the 1ath light emitting device 130a and the 1bth light emitting device 130b is determined to be normal, the 1ath light emitting device 130a is not be used and only the 1bth light emitting device 130b can be used. Therefore, even if the plurality of the same light emitting devices ED are transferred to one pixel PX, only one light emitting device ED can be finally used.

In this case, any one of the pair of light emitting devices ED can be referred to as a main or primary light emitting device ED, and the other light emitting device ED can be referred to as a redundancy light emitting device ED. The redundancy light emitting device ED can be an extra light emitting device ED transferred to prepare for a defect in the main light emitting device ED. When the main light emitting device ED is defective, the redundancy light emitting device ED can be used instead of the main light emitting device ED. The main light emitting device ED and the redundancy light emitting device ED are transferred to one pixel PX, thereby minimizing deterioration of display quality due to defects in the main light emitting device ED and the redundancy light emitting device ED.

For example, the 1ath light emitting device 130a, the 2ath light emitting device 140a, and the 3ath light emitting device 150a transferred to one pixel PX can be used as the main light emitting device ED, and the 1bth light emitting device 130b, the 2bth light emitting device 140b, and the 3bth light emitting device 150b can be used as the redundancy light emitting device ED.

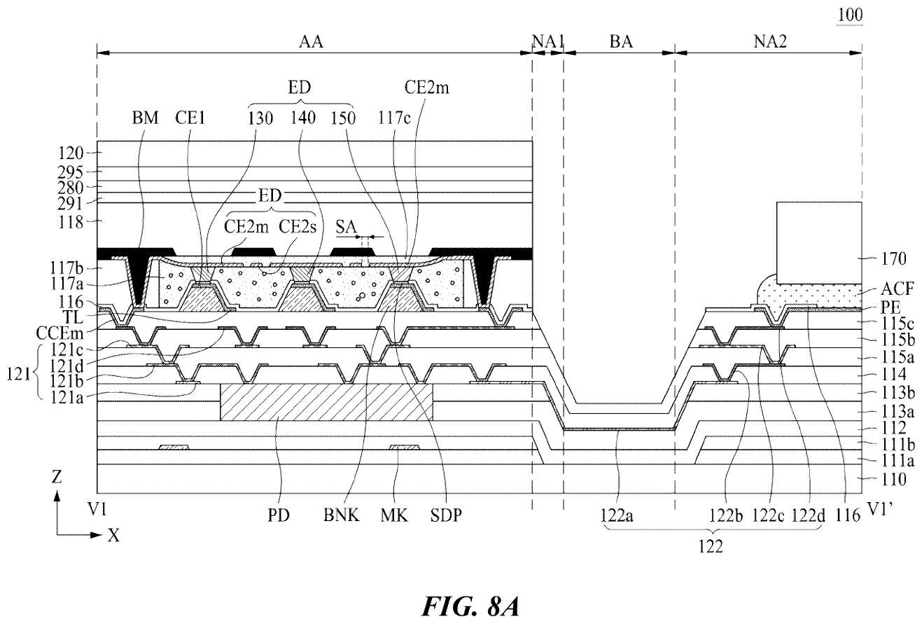

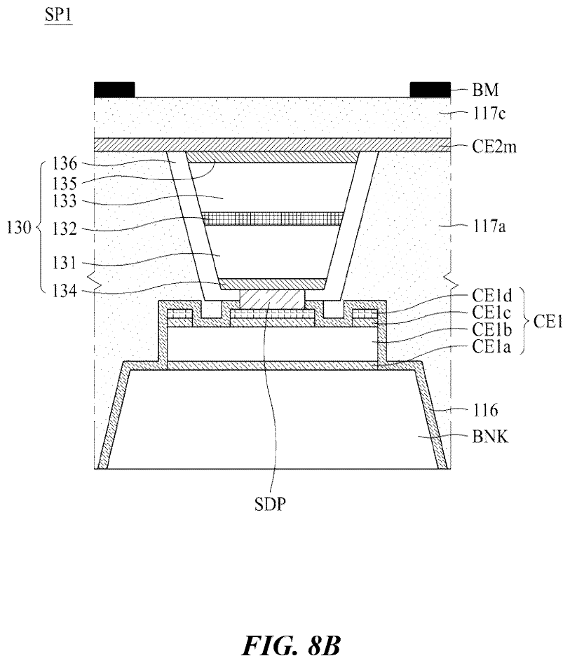

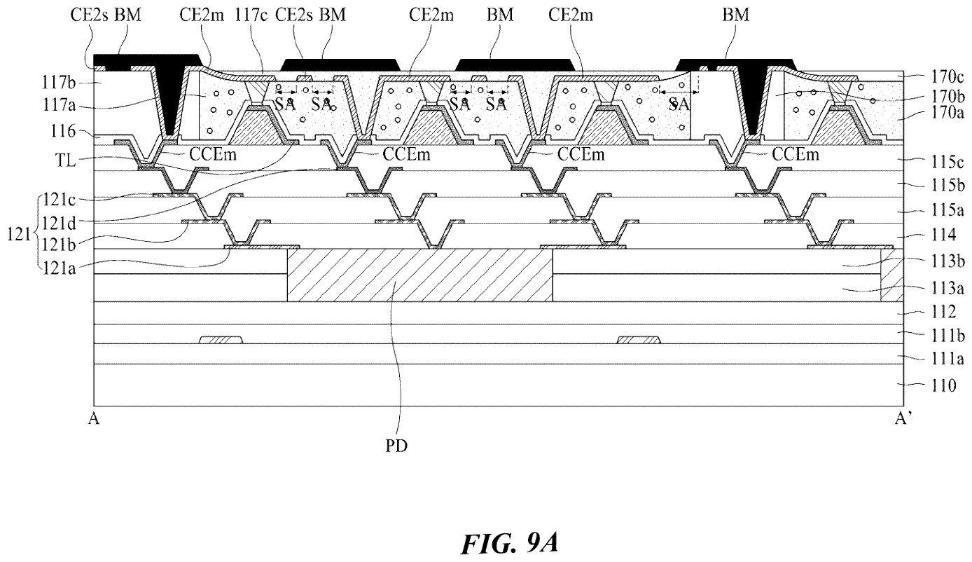

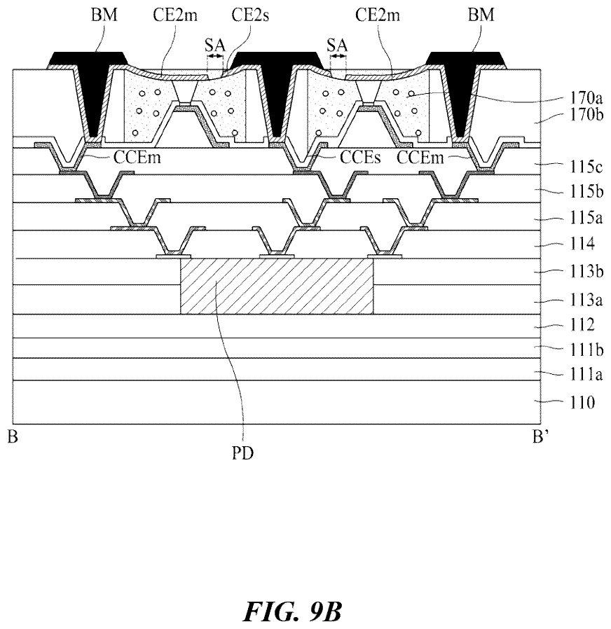

FIG. 8A is an exemplary diagram illustrating a cross-sectional surface taken along a line V1-V1′ illustrated in FIG. 3, FIG. 8B is a cross-sectional view of a light emitting device applied to a display apparatus according to an embodiment of the present disclosure, FIG. 9A is an exemplary diagram illustrating a cross-sectional surface taken along a line A-A ‘illustrated in FIG. 7A, and FIG. 9B is an exemplary diagram illustrating a cross-sectional surface taken along a line B-B’ illustrated in FIG. 7A. For example, FIG. 8A is a cross-sectional view of the display area AA, the first non-display area NA, the bending area BA, and the second non-display area NA2, and FIG. 8B is a cross-sectional view of the light emitting device ED in the display area AA.

First, referring to FIG. 8A, a first buffer layer 111a and a second buffer layer 111b can be disposed in the remaining area of the substrate 110 except the bending area BA.

The first buffer layer 111a and the second buffer layer 111b can be disposed in the display area AA, the first non-display area NA1, and the second non-display area NA2. The first buffer layer 111a and the second buffer layer 111b can reduce penetration of moisture or impurities through the substrate 110. The first buffer layer 111a and the second buffer layer 111b can be formed of an inorganic insulating material. For example, each of the first buffer layer 111a and the second buffer layer 111b can be formed of a single layer composed of silicon oxide (SiOx) or silicon nitride (SiNx) or a multilayer including at least on of silicon oxide (SiOx) and silicon nitride (SiNx), but embodiments of the present disclosure are not limited thereto.

For example, portions of the first buffer layer 111a and the second buffer layer 111b on the bending area BA can be removed. An upper surface of the substrate 110 disposed in the bending area BA cannot be covered by the first buffer layer 111a and the second buffer layer 111b to be exposed. When the first buffer layer 111a and the second buffer layer 111b made of the inorganic insulating material are removed from the bending area BA, cracks, which can occur during bending, in the first buffer layer 111a and the second buffer layer 111b can be minimized.

A plurality of alignment keys M K can be disposed between the first buffer layer 111a and the second buffer layer 111b. The plurality of alignment keys M K can be formed to identify a position of the pixel driving circuit PD during a manufacturing process of the display panel 100. For example, the plurality of alignment keys M K can align the position of the pixel driving circuit PD transferred onto an adhesive layer 112. However, the plurality of alignment keys M K can be omitted.

An adhesive layer 112 can be disposed on the second buffer layer 111b. The adhesive layer 112 can be disposed in the display area AA, the first non-display area NA1, the bending area BA, and the second non-display area NA2. A portion of the adhesive layer 112 can be removed from the non-display area NA including the bending area BA. For example, the adhesive layer 112 can be formed of any one of an Adhesive polymer, an epoxy resin, a UV curable resin, a polyimide-based resin, an acrylate-based material, a urethane-based material, and a polydimethylsiloxane (PDMS).

In the display area AA, the pixel driving circuit PD can be disposed on the adhesive layer 112. The pixel driving circuit PD can be mounted on the adhesive layer 112 through a transfer process, but embodiments of the present disclosure are not limited thereto.

A first protective layer 113a and a second protective layer 113b can be disposed on the adhesive layer 112 and the pixel driving circuit PD. The first protective layer 113a and the second protective layer 113b can surround a side surface of the pixel driving circuit PD. For example, the second protective layer 113b can cover at least a portion of an upper surface of the pixel driving circuit PD. At least one of the first protective layer 113a and the second protective layer 113b disposed on the bending area BA can be omitted. For example, the first protective layer 113a can be entirely disposed in the display area AA and the non-display area NA. Also, the second protective layer 113b can be partially disposed in the display area AA, the first non-display area NA1, and the second non-display area NA2. Moreover, the second protective layer 113b may not be disposed in the bending area BA.

The first protective layer 113a and the second protective layer 113b can be formed of an organic insulating material. For example, the first protective layer 113a and the second protective layer 113b can be formed of a photo resist, polyimide (PI), a photo acryl-based material, or the like. The first protective layer 113a and the second protective layer 113b can be an overcoating layer or an insulating layer.

According to the present disclosure, a plurality of first connection lines 121 can be disposed on the second protective layer 113b in the display area AA. The first connection line 121 can be a line for electrically connecting the pixel driving circuit PD to other devices. The pixel driving circuit PD can be electrically connected to the signal line TL through the first connection line 121.

For example, the pixel driving circuit PD can be connected to the main cathode electrode line through the first connection line 121, and the main cathode electrode line can be connected to the main contact electrode CCEm. Also, the pixel driving circuit PD can be connected to the shield electrode line through the first connection line 121, and the shield electrode line can be connected to the shield contact electrodes CCEs. However, the first connection line 121 can be a signal line TL.

The first connection line 121 can include a 1ath connection line 121a, a 1bth connection line 121b, a 1cth connection line 121c, and a 1dth connection line 121d.

The plurality of 1ath connection lines 121a can be disposed on the second protective layer 113b. The plurality of 1ath connection lines 121a can be electrically connected to the pixel driving circuit PD. The 1ath connection lines 121a can transmit voltages output from the pixel driving circuit PD to the first electrode CE1 or the second electrode CE2.

A third protective layer 114 can be disposed on the second protective layer 113b. The third protective layer 114 can be disposed on the entire display area AA and the non-display area NA. In the bending area BA, the third protective layer 114 can disposed on or cover a side surface of the second protective layer 113b and an upper surface of the first protective layer 113a. The third protective layer 114 can be formed of an organic insulating material. The third protective layer 114 can be formed of a photo resist, polyimide (PI), a photo acryl-based material, or the like. For example, the first protective layer 113a, the second protective layer 113b, and the third protective layer 114 can be formed of the same material, but embodiments of the present disclosure are not limited thereto.

The plurality of 1bth connection lines 121b can be disposed on the third protective layer 114. The 1bth connection lines 121b can be connected to the pixel driving circuit PD through the 1ath connection lines 121a or can be directly connected to the pixel driving circuit PD. For example, a portion of the 1bth connection line 121b can be directly connected to the pixel driving circuit PD through a contact hole of the third protective layer 114. The other portion of the 1bth connection line 121b can be electrically connected to the 1ath connection line 121a through a contact hole of the third protective layer 114. However, embodiments of the present disclosure are not limited thereto. For example, the voltage output from the pixel driving circuit PD can be transmitted to the first electrode CE1 or the second electrode CE2 through a connection line different from the 1bth connection lines 121b.

A first insulating layer 115a can be disposed on the plurality of 1bth connection lines 121b. The first insulating layer 115a can be disposed in the entire display area AA and the non-display area NA, but embodiments of the present disclosure are not limited thereto. The first insulating layer 115a can be formed of an organic insulating material. The first insulating layer 115a can be formed of a photo resist, polyimide (PI), a photo acryl-based material, or the like.

The plurality of 1cth connection lines 121c can be disposed on the first insulating layer 115a. The 1cth connection lines 121c can be electrically connected to the 1bth connection lines 121b. For example, the 1cth connection lines 121c can be electrically connected to the 1bth connection lines 121b through a contact hole of the first insulating layer 115a.

A second insulating layer 115b can be disposed on the plurality of 1cth connection lines 121c. The second insulating layer 115b can be disposed in the remaining area except for the bending area BA. The second insulating layer 115b can be disposed in the display area AA, the first non-display area NA1, and the second non-display area NA2. For example, at least a portion of the second insulating layer 115b disposed in the bending area BA can be removed. The second insulating layer 115b can be formed of an organic insulating material, but embodiments of the present disclosure are not limited thereto. For example, the second insulating layer 115b can be formed of a photo resist, polyimide (PI), a photo acryl-based material, or the like.

The plurality of 1dth connection lines 121d can be disposed on the second insulating layer 115b. The 1dth connection lines 121d can be electrically connected to the 1cth connection lines 121c. For example, the 1dth connection lines 121d can be electrically connected to the 1cth connection lines 121c through a contact hole of the second insulating layer 115b.

The 1dth connection line 121d can be connected to the main contact electrode CCEm through a contact hole of a third insulating layer 115c, and thus, the main contact electrode CCEm and the pixel driving circuit PD can be electrically connected to the first connection line 121.

That is, the main contact electrode CCEm connected to the main cathode electrode CEm can be electrically connected to the pixel driving circuit PD through the 1dth connection line 121d, the 1cth connection line 121c, the 1bth connection line 121b, and the 1ath connection line 121a.

Also, the 1dth connection line 121d can be connected to the shield contact electrode CCEs through a contact hole of the third insulating layer 115c, and accordingly, the shield contact electrode CCEs and the pixel driving circuit PD can be electrically connected to each other by the first connection line 121.

In this case, the 1dth connection line 121d can be the main cathode electrode line or the shield electrode line.

However, the 1dth connection line 121d can be directly connected to the signal line TL through a contact hole disposed in the third insulating layer 115c, or can be electrically connected to the signal ling TL through other additional line or electrode, and thus, the signal line TL and the pixel driving circuit PD can be electrically connected to each other by the first connection line 121.

The signal line TL can be formed of at least one of the 1ath to 1dth connection lines 121a to 121d, or can be connected to the first connection line 121.

A plurality of second connection lines 122 can be disposed on the second protective layer 113b in the non-display area NA. The second connection lines 122 can be a line for transmitting a signal received from the flexible circuit board (or a flexible film) 170 and a printed circuit board 160 to the pixel driving circuit PD of the display area AA.

For example, the plurality of second connection lines 122 can be electrically connected to the plurality of pad electrodes PE to receive signals from flexible circuit boards (or flexible films) 170 and printed circuit boards 160.

For example, the plurality of second connection lines 122 can extend from the pad part PAD toward the display area AA to transmit signals to the lines of the display area AA. In this case, each of the plurality of second connection lines 122 can function as link lines LL (showed in FIG. 3). The second connection line 122 can include a 2ath connection line 122a, a 2bth connection line 122b, a 2cth connection line 122c, and a 2dth connection line 122d.

The plurality of 2ath connection lines 122a can be disposed on the second protective layer 113b. The plurality of 2ath connection lines 122a can extend from the second non-display area NA2 to the bending area BA and the first non-display area NA1. The plurality of 2ath connection lines 122a can transmit signals received from the flexible circuit board (or flexible film 170 and the printed circuit board 160 to the pixel driving circuit PD of the display area AA. Accordingly, the 2ath connection line 122a can be electrically connected to the pad electrode PE and the pixel driving circuit PD, respectively. For example, the 2ath connection line 122a can extend to the display area AA to be directly connected to the pixel driving circuit PD in the display area AA, or can be electrically connected to the pixel driving circuit PD through other additional line or electrodes. Also, the 2ath connection line 122a can be electrically connected to the pad electrode PE in the second non-display area NA2 through the 2bth connection line 122b, the 2cth connection line 122c, and the 2dth connection line 122d. Therefore, the pixel driving circuit PD and the pad electrode PE can be electrically connected by the second connection line 122.

The plurality of 2bth connection lines 122b can be disposed on the third protective layer 114. 2bth connection lines 122b can be disposed in the second non-display area NA2. The 2bth connection lines 122b can be electrically connected to the 2ath connection lines 122a through a contact hole of the third protective layer 114. Therefore, signals from the flexible circuit board (or flexible film) 170 and the printed circuit board 160 can be transmitted to the 2ath connection lines 122a through the 2bth connection lines 122b.

The 2cth connection line 122c can be disposed on the first insulating layer 115a. The 2cth connection line 122c can be disposed in the second non-display area NA2. The 2cth connection line 122c can be electrically connected to the 2bth connection line 122b through a contact hole of the first insulating layer 115a. Accordingly, signals from the flexible circuit board (or flexible film) 170 and the printed circuit board 160 can be transmitted to the 2ath connection line 122a through the 2cth connection line 122c and the 2bth connection line 122b.

The 2dth connection line 122d can be disposed on the second insulating layer 115b. The 2dth connection line 122d can be disposed in the second non-display area NA2. The 2dth connection line 122d can be electrically connected to the 2cth connection line 122c through a contact hole of the second insulating layer 115b. Accordingly, signals from the flexible circuit board (or flexible film) 170 and the printed circuit board 160 can be transmitted to the 2ath connection line 122a through the 2dth connection line 122d, the 2cth connection line 122c, and the 2bth connection line 122b.

In addition, the 2ath connection line 122a can extend to the display area AA through the bending area BA, and can be electrically connected to the pixel driving circuit PD in the display area AA.

Accordingly, the pad electrode PE provided in the second non-display area NA2 can be electrically connected to the pixel driving circuit PD provided in the display area AA through the 2dth connection line 122d, the 2cth connection line 122c, and the 2bth connection line 122b in the second non-display area NA2, and the 2ath connection line 122a in the bending area BA.

Each of the first connection line 121 and the second connection line 122 can be formed of a conductive material having excellent ductility or various conductive materials used in the display area AA. For example, the second connection line 122 partially disposed in the bending area BA can be formed of a conductive material having excellent ductility, such as gold (Au), silver (Ag), or aluminum (Al). For another example, each of the first connection lines 121 and the second connection lines 122 can be formed of molybdenum (Mo), chromium (Cr), titanium (Ti), nickel (Ni), neodymium (Nd), copper (Cu), an alloy of silver (Ag) and magnesium (M g), or an alloy thereof.

A third insulating layer 115c can be disposed on the plurality of first connection lines 121 and the plurality of second connection lines 122. The third insulating layer 115c can be disposed in the remaining area except for the bending area BA. The third insulating layer 115c can be disposed in the display area AA, the first non-display area NA1, and the second non-display area NA2. At least a portion of the third insulating layer 115c in the bending area BA can be removed. The third insulating layer 115c can be formed of an organic insulating material, but embodiments of the present disclosure are not limited thereto. For example, the third insulating layer 115c can be formed of a photo resist, polyimide (PI), a photo acryl-based material, or the like.

A bank BNK can be disposed on the third insulating layer 115c in the display area AA. The bank BNK can overlap the sub-pixel. The bank BNK may not be disposed in the first non-display area NA1, the second non-display area NA2, and the bending area BA. One or more light emitting devices ED of the same type can be disposed on an upper portion of the bank BNK.

In the display area AA, a plurality of signal lines TL's can be disposed on the third insulating layer 115c. The signal line TL can be disposed between the plurality of banks BNK. For example, the signal line TL can be disposed adjacent to any one of the plurality of banks BNK. The signal line TL can be electrically connected to the first connection line 121, for example, the 1dth connection line 121d.

The signal line TL can be a main cathode electrode line connected to the main contact electrode CCEm or a shield electrode line connected to the shield contact electrodes CCEs.

A plurality of main contact electrodes CCEm can be disposed on the third insulating layer 115c in the display area AA. The main contact electrode CCEm can supply the cathode voltage or the touch driving signal transmitted from the pixel driving circuit PD to the main cathode electrode CE2m. The main contact electrode CCE can be electrically connected to the first connection line 121, for example, the 1dth connection line 121d through the main cathode electrode line.

A plurality of shield contact electrodes CCEs can be disposed on the third insulating layer 115c in the display area AA. The shield contact electrode CCEs can supply the shield voltage or the touch driving signal transmitted from the pixel driving circuit PD to the shield electrode CE2s. The shield contact electrode CCEs can be electrically connected to the first connection line 121, for example, the 1dth connection line 121d through the shield electrode line.

A first electrode CE1 can be disposed on the bank BNK. For example, the first electrode CE1 can extend from the adjacent signal line TL to an upper portion of the bank BNK. The first electrode CE1 can be disposed on an upper surface of the bank BNK and a side surface of the bank BNK. For example, the first electrode CE1 can extend from the signal line TL on an upper surface of the third insulating layer 115c to the side surface of the bank BNK and the upper surface of the bank BNK. The first electrode CE1 can be integrally formed with the signal line TL.

Referring to FIG. 8B, the first electrode CE1 can include a plurality of conductive layers. For example, the first electrode CE1 can include a first conductive layer CE1a, a second conductive layer CE1b, a third conductive layer CE1c, and a fourth conductive layer CE1d.

The first conductive layer CE1a can be disposed on the bank BNK. The second conductive layer CE1b can be disposed on the first conductive layer CE1a. The third conductive layer CE1c can be disposed on the second conductive layer CE1b, and the fourth conductive layer CE1d can be disposed on the third conductive layer CE1c. For example, the first conductive layer CE1a, the second conductive layer CE1b, the third conductive layer CE1c, and the fourth conductive layer CE1d can be formed of titanium (Ti), molybdenum (Mo), aluminum (Al), or titanium (Ti) and indium tin oxide (ITO), but embodiments of the present disclosure are not limited thereto.

Some of the plurality of conductive layers included in the first electrode CE1 having high reflection efficiency can be used as an alignment key and/or a reflector for aligning the light emitting device ED. For example, the second conductive layer CE1b among the plurality of conductive layers of the first electrode CE1 can include a reflective material. For example, the second conductive layer CE1b can include aluminum (Al). In this case, the second conductive layer CE1b can be used as a reflective plate. Also, due to a high reflection efficiency of the second conductive layer CE1b, identification can be easily performed in a manufacturing process, and thus an arrangement position or a transfer position of the light emitting device ED can be arranged with respect to the second conductive layer CE1b.

For example, in order to use the second conductive layer CE1b as the reflective plate, the third conductive layer CE1c and the fourth conductive layer CE1d covering the second conductive layer CE1b can be partially removed or etched. Portions of the third and fourth conductive layers CE1c and CE1d disposed on the bank BNK can be removed or etched to expose an upper surface of the second conductive layer CE1b. A central portion and an edge portion of the third and fourth conductive layers CE1c and CE1d on which a solder pattern SDP is disposed can remain, and remaining portions except for the center portion and the edge portion of the third and fourth conductive layers CE1c and CE1d can be removed. The central portion and the edge portion of each of the third conductive layer CE1c made of titanium (Ti) and the fourth conductive layer CE1d made of indium tin oxide (ITO) may not be etched. Thus, another conductive layer of the first electrode CE1 can be prevented from being corroded by a TMAH (Tetra Methyl Ammonium Hydroxide) solution used in a mask process of the first electrode CE1.

The first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which has high adhesion to the solder pattern SDP and has corrosion resistance and acid resistance.

The first conductive layer CE1a, the second conductive layer CE1b, the third conductive layer CE1c, and the fourth conductive layer CE1d can be sequentially deposited and then patterned by a photolithography process and an etching process.

Each of the signal line TL, the main contact electrode CCEm, the shield contact electrode CCEs, and the pad electrode PE disposed on the same layer as the first electrode CE1 can be formed of multiple layers of conductive materials, but embodiments of the present disclosure are not limited thereto. For example, each of the signal line TL, the main contact electrode CCEm, the shield contact electrode CCEs, and the pad electrode PE can be formed of multiple layers in which indium tin oxide (ITO), titanium (Ti), aluminum (Al), and titanium (Ti) are stacked.

A solder pattern SDP can be disposed on the first electrode CE1 in each of the plurality of sub-pixels. The solder pattern SDP can bond the light emitting device ED to the first electrode CE1. The first electrode CE1 and the light emitting device ED can be electrically connected to each other through eutectic bonding using the solder pattern SDP, but embodiments of the present disclosure are not limited thereto. For example, when the solder pattern SDP is formed of indium (In), and the anode electrode 134 of the light emitting device ED is formed of gold (Au), the solder pattern SDP and the anode electrode 134 can be bonded to each other by applying heat and pressure in the transfer process of the light emitting device ED. The light emitting device ED can be bonded to the solder pattern SDP and the first electrode CE1 without a separate adhesive member through eutectic bonding. The solder pattern SDP can be formed of indium (In), tin (Sn), or alloys thereof. The solder pattern SDP can be a bonding pad or the like.

A passivation layer 116 can be disposed on the plurality of signal lines TL, the plurality of first electrodes CE1, the plurality of main contact electrodes CCEm, the shield contact electrode CCEs, and the third insulation layer 115c. For example, the passivation layer 116 can be disposed in the display area AA, the first non-display area NA1, and the second non-display area NA2. A portion of the passivation layer 116 disposed in the bending area BA can be removed. A portion of the passivation layer 116 covering the plurality of pad electrodes PE can be removed in the second non-display area NA2. A portion of the passivation layer 116 covering the plurality of main contact electrodes CCEm and the shield contact electrode CCEs can be removed in the display area AA. The passivation layer 116 covering the solder pattern SDP can be removed in the display area AA. The passivation layer 116 can cover the first electrode CE1. The passivation layer 116 can cover a portion of the exposed upper surface of a second conductive layer CE1b.

Because the passivation layer 116 covers the remaining areas while exposing a portion of the plurality of pad electrodes PE, a portion of the plurality of main contact electrodes CCEm, a portion of the plurality of shield contact electrode, and a portion of the solder pattern SDP, penetration of moisture or impurities flowing into the light emitting device ED can be reduced. The passivation layer 116 can be formed of a single layer or multiple layers including silicon oxide (SiOx) or silicon nitride (SiNx). The passivation layer 116 can be a protective layer or an insulating layer. The passivation layer 116 can include a hole exposing the solder pattern SDP and holes exposing the main contact electrode CCEm and the shield contact electrode CCEs.

In each of the plurality of sub-pixels, the light emitting device ED can be disposed on the solder pattern SDP. The first light emitting device 130 can be disposed in the first sub-pixel SP1. The second light emitting device 140 can be disposed in the second sub-pixel SP2. The third light emitting device 150 can be disposed in the third sub-pixel SP3.

The light emitting device ED can be formed on silicon wafers by means of metal organic vapor deposition (MOCVD), chemical vapor deposition (CVD), plasma-enhanced chemical vapor deposition (PECVD), molecular beam growth (MBE), hydride vapor deposition (HVPE), or sputtering, but embodiments of the present disclosure are not limited thereto.

The first light emitting device 130 can include an anode 134, a first semiconductor layer 131, an active layer 132, a second semiconductor layer 133, a cathode electrode 135, and an encapsulation layer 136. For example, the encapsulation layer 136 may not be included in the first light emitting device 130.

The first semiconductor layer 131 can be disposed on the solder pattern SDP. The second semiconductor layer 133 can be disposed on the first semiconductor layer 131.

For example, each of the first semiconductor layer 131 and the second semiconductor layer 133 can formed of a compound semiconductor such as a group III-V or a group II-VI, and can be doped with impurities (or dopants). For example, one of the first semiconductor layer 131 and the second semiconductor layer 133 can be a semiconductor layer doped with n-type impurities, and the other can be a semiconductor layer doped with p-type impurities. For example, each of the first semiconductor layer 131 and the second semiconductor layer 133 can be a layer in which an n-type or p-type impurity is doped into a material such as gallium nitride (GaN), gallium phosphide (GaP), gallium arsenic phosphide (GaAsP), aluminum gallium indium phosphide (AlGaInP), indium aluminum phosphide (InAlP), aluminum gallium nitride (AlGaN), aluminum indium nitride (AlInN), aluminum gallium nitride (AlInGaN), aluminum gallium arsenic (AlGaAs), gallium arsenic (AlGaAs), or a material such as gallium arsenic (GaAs). The n-type impurity can be silicon (Si), germanium (Ge), selenium (Se), carbon (C), tellurium (Te), tin (Sn), or the like. The p-type impurity can be magnesium (M g), zinc (Zn), calcium (Ca), strontium (Sr), barium (Ba), beryllium (Be), or the like,

Each of the first semiconductor layer 131 and the second semiconductor layer 133 can be a nitride semiconductor including the n-type impurity or a nitride semiconductor including the p-type impurity. For example, the first semiconductor layer 131 can be a nitride semiconductor including the p-type impurity, and the second semiconductor layer 133 can be a nitride semiconductor including the n-type impurity.

The active layer 132 can be disposed between the first semiconductor layer 131 and the second semiconductor layer 133. The active layer 132 can emit light by receiving holes and electrons from the first semiconductor layer 131 and the second semiconductor layer 133. For example, the active layer 132 can be formed of one of a single well structure, a multi-well structure, a single quantum well structure, a multi-quantum well (MQW) structure, a quantum dot structure, and a quantum line structure. The active layer 132 can be formed of indium gallium nitride (InGaN), gallium nitride (GaN), or the like.

For another example, the active layer 132 can include a multi-quantum well (MQW) structure having a well layer and a barrier layer having a band gap higher than that of the well layer. For example, the active layer 132 can include InGaN as a well layer, and can include an AlGaN layer as a barrier layer.

The anode 134 can be disposed between the first semiconductor layer 131 and the solder pattern SDP. The anode 134 can electrically connect the first semiconductor layer 131 to the first electrode CE1. The anode voltage output from the pixel driving circuit PD can be applied to the first semiconductor layer 131 through the signal line TL, the first electrode CE1, and the anode 134. The anode 134 can be formed of a conductive material capable of eutectic bonding with the solder pattern SDP. For example, the anode 134 can be formed of gold (Au), tin (Sn), tungsten (W), silicon (Si), silicon (Ag), titanium (Ti), iridium (Ir), chromium (In), indium (Zn), zinc (Pb), lead (Ni), platinum (Pt), copper (Cu), or alloys thereof.

The cathode electrode 135 can be disposed on the second semiconductor layer 133. For example, the cathode electrode 135 can electrically connect the second semiconductor layer 133 to the second electrode CE2. The cathode voltage output from the pixel driving circuit PD can be applied to the second semiconductor layer 133 through the contact electrode CCE, the second electrode CE2, and the cathode electrode 135. The cathode electrode 135 can be formed of a transparent conductive material to allow light emitted from the light emitting device ED to be directed to an upper portion of the light emitting device ED. For example, the cathode electrode 135 can be formed of a material such as indium tin oxide (ITO), indium zinc oxide (IZO), indium gallium zinc oxide (IGZO), or the like.

The encapsulation layer 136 can be disposed on at least a portion of each of the first semiconductor layer 131, the active layer 132, the second semiconductor layer 133, the anode 134, and the cathode electrode 135. For example, the encapsulation layer 136 can surround at least a portion of each of the first semiconductor layer 131, the active layer 132, the second semiconductor layer 133, the anode 134, and the cathode electrode 135.

The encapsulation layer 136 can protect the first semiconductor layer 131, the active layer 132, and the second semiconductor layer 133. The encapsulation layer 136 can be disposed on a side surface of the first semiconductor layer 131, a side surface of the active layer 132, and a side surface of the second semiconductor layer 133.

The encapsulation layer 136 can be disposed on at least a portion of the anode 134 and the cathode electrode 135. For example, the encapsulation layer 136 can be disposed on the edge portion (or one side) of the anode 134 and the edge portion (or one side) of the cathode electrode 135. At least a portion of the anode 134 can be exposed by the encapsulation layer 136, and thus the anode 134 can connect with the solder pattern SDP. For example, at least a portion of the cathode electrode 135 can be exposed by the encapsulation layer 136, and thus the cathode electrode 135 can connect with the main cathode electrode CE2m. The encapsulation layer 136 can be formed of an insulating material such as silicon nitride (SiNx) or silicon oxide (SiOx).

For another example, the encapsulation layer 136 can be a layer in which a reflective material is distributed in a resin layer. The encapsulation layer 136 can be manufactured as a reflector having various structures. Light emitted from the active layer 132 can be reflected upward by the encapsulation layer 136 so that light extraction efficiency can be improved. In this case, the encapsulation layer 136 can be a reflective layer.

The light emitting device ED has been described as a vertical structure, but embodiments of the present disclosure are not limited thereto. For example, the light emitting device ED can have a lateral structure or a flip chip structure.

Although the first light emitting device 130 has been described above with reference to FIG. 8B, the second light emitting device 140 and the third light emitting device 150 can have substantially the same structure as the first light emitting device 130. For example, each of the second light emitting device 140 and the third light emitting device 150 can have substantially the same configuration as the first semiconductor layer 131, the active layer 132, the second semiconductor layer 133, the anode 134, the cathode electrode 135, and the encapsulation layer 136.

According to the present disclosure, as shown in FIGS. 8A and 8B, a first optical layer 117a surrounding the plurality of light emitting devices ED can be disposed in the display area AA. For example, the first optical layer 117a can cover the side surfaces of the light emitting devices ED and the side surfaces of the plurality of banks BNK. The first optical layer 117a can cover a portion of the passivation layer 116. The first optical layer 117a can be disposed between the main cathode electrode CE2m, the passivation layer 116, and the plurality of light emitting devices.

The first optical layer 117a can be disposed between the plurality of light emitting devices ED included in one pixel PX and cover the plurality of light emitting devices ED included in one pixel PX. Also, the first optical layer 117a can be disposed between the plurality of banks BNK included in one pixel PX and cover the plurality of light emitting devices ED included in one pixel PX. For example, the first optical layer 117a can extend in the first direction X, and the plurality of first optical layers 117a can be spaced apart from each other in the second direction Y in a plan view. For example, the first optical layer 117a can be disposed between the passivation layer 116 and the main cathode electrode CE2m to surround the side surface of the light emitting device ED and the side surface of the bank BNK. The first optical layer 117a can be referred to as a diffusion layer, a sidewall diffusion layer, or the like.

The first optical layer 117a can include an organic insulating material in which fine particles are distributed. For example, the first optical layer 117a can be formed of siloxane in which fine metal particles such as titanium dioxide (TiO2) particles are distributed. Light from the plurality of light emitting devices ED can be scattered by fine particles distributed in the first optical layer 117a and emitted to an outside of the display panel 100. Accordingly, the first optical layer 117a can improve extraction efficiency of light emitted from the plurality of light emitting devices ED.

The first optical layer 117a can be disposed in each of the plurality of pixels PX or can be disposed in some pixels PX disposed in the same row. For example, as shown in FIG. 8A, the first optical layer 117a can be disposed in each of the plurality of pixels PX. Also, the plurality of pixels PX can share one first optical layer 117a. For another example, each of the plurality of sub-pixels can separately include a first optical layer 117a.

The second optical layer 117b can be disposed on the passivation layer 116 in the display area AA. For example, the second optical layer 117b can surround the first optical layer 117a. For example, the second optical layer 117b can be in contact with a side surface of the first optical layer 117a. For example, the second optical layer 117b can be disposed in an area between the plurality of pixels PX. However, embodiments of the present disclosure are not limited thereto. The second optical layer 117b can be referred to as a diffusion layer, a window diffusion layer, or the like.

The second optical layer 117b can be formed of an organic insulating material, but embodiments of the present disclosure are not limited thereto. The second optical layer 117b can be formed of the same material as the first optical layer 117a, but embodiments of the present disclosure are not limited thereto. For example, the first optical layer 117a can include fine particles, and the second optical layer 117b may not include fine particles. For example, the second optical layer 117b can be formed of siloxane.

A thickness of the first optical layer 117a can be less than a thickness of the second optical layer 117b. Accordingly, in a plan view, an area in which the first optical layer 117a is disposed can include a concave portion recessed from an upper surface of the second optical layer 117b.

The main cathode electrode CE2m can be disposed on the first optical layer 117a and the second optical layer 117b. The main cathode electrode CE2m can be electrically connected to the main contact electrode CCEm through a contact hole in the second optical layer 117b. The main cathode electrode CE2m can be disposed on a plurality of light emitting devices ED, but can be disposed on one light emitting device ED, as shown in FIG. 8A. The main cathode electrode CE2m can include a transparent conductive oxide such as indium tin oxide (ITO) or indium zinc oxide (IZO). The main cathode electrode CE2m can be disposed to be in contact with the cathode electrode 135. The main cathode electrode CE2m can overlap the entire first optical layer 117a, and can overlap a portion of the second optical layer 117b.

The shield electrode CE2s can be disposed on the first optical layer 117a and the second optical layer 117b. The shield electrode CE2s can be electrically connected to the shield contact electrode CCEs through a contact hole in the second optical layer 117b or the first optical layer 117a. The shield electrode CE2s can be disposed between the light emitting devices EDs on an upper end of the light emitting device ED. The shield electrode CE2s can be formed of the same material as that of the main cathode electrode CE2m, or can be formed of a different material.

The second electrode CE2 including a plurality of main cathode electrodes CE2m and one shield electrode CE2s can extend continuously in the first direction X of the substrate 110. Accordingly, the second electrode CE2 can be connected in common to at least two pixels PX arranged in the first direction X of the substrate 110. For example, the second electrode CE2 can be connected in common to at least two pixels PX. Hereinafter, for convenience of description, a display apparatus according to the present disclosure will be described by using a second electrode CE2 including a plurality of main cathode electrodes CE2m and one shield electrode CE2s.

The second electrode CE2, for example, the main cathode electrode CE2m, can be provided on upper ends of the first optical layer 117a, the second optical layer 117b, and the light emitting device ED. An area in which the first optical layer 117a is disposed can include a concave portion recessed inwardly from the upper surface of the second optical layer 117b. Accordingly, because a first portion of the second electrode CE2 disposed on the first optical layer 117a is disposed along the concave portion, the first portion of the second electrode CE2 disposed on the first optical layer 117a can be disposed at a lower position than a second portion of the second electrode CE2 disposed on the second optical layer 117b.

A third optical layer 117c can be disposed on the second electrode CE2. The third optical layer 117c can be disposed to overlap a plurality of light emitting devices ED and the first optical layer 117a. In this case, the third optical layer 117c may not to overlap the second optical layer 117b. Because the third optical layer 117c is disposed on the second electrode CE2 and a plurality of light emitting devices ED, the third optical layer 117c can improve a spot Mura that can occur in some of a plurality of light emitting devices ED. For example, when the plurality of light emitting devices ED is transferred on the substrate 110 of the display panel 100, a region in which a gap between the plurality of light emitting devices ED is not uniform due to a process deviation, or the like can occur. When the gap between the plurality of light emitting devices ED is not uniform, a light emitting area of each of the plurality of light emitting devices ED can be non-uniformly disposed, and thus a spot (or mura) can be recognized by a user.

Because the third optical layer 117c for uniformly diffusing light is formed on an upper portion of the plurality of light emitting devices ED, it is possible to reduce visibility of light emitted from some light emitting devices ED as spots (or mura). Therefore, because the light emitted from the plurality of light emitting devices ED is uniformly diffused by the third optical layer 117c and extracted to the outside of the display panel 100, the luminance uniformity of the display apparatus can be improved.

The third optical layer 117c can be formed of an organic insulating material in which fine particles are distributed, but embodiments of the present disclosure are not limited thereto. For example, the third optical layer 117c can be formed of siloxane in which fine metal particles such as titanium dioxide (TiO2) particles are distributed. However, the third optical layer 117c can be formed of the same material as the first optical layer 117a. The third optical layer 117c can be referred to as a diffusion layer, an upper diffusion layer, or the like.

Light from the plurality of light emitting devices ED can be scattered by fine particles distributed in the third optical layer 117c and emitted to the outside of the display panel 100. The third optical layer 117c can evenly mix the light emitted from the plurality of light emitting devices ED to further improve luminance uniformity of the display apparatus. In addition, light extraction efficiency of the display apparatus can be improved by the light scattered from the plurality of fine particles, and thus the display apparatus can be driven at a low power.

In the display area AA, a black matrix BM can be disposed on the main cathode electrode CE2m, the shield electrode CE2s, the first optical layer 117a, the second optical layer 117b, and the third optical layer 117c. For example, the black matrix BM can fill a contact hole in the second optical layer 117b in order to connect the main cathode electrode CE2m to the main contact electrode CCEm. Because the black matrix BM can cover the display area AA, color mixture of light of the plurality of sub-pixels and reflection of external light can be reduced. For example, because the black matrix BM is also disposed within a contact hole in which the main cathode electrode CE2m and the main contact electrode CCEm are connected to each other, light leakage between the plurality of adjacent sub-pixels can be prevented.

The black matrix BM is not provided on an upper end of the light emitting device ED. Accordingly, light generated from the light emitting device ED can be output to the outside.

The black matrix BM can be formed of an opaque material, but embodiments of the present disclosure are not limited thereto. For example, the black matrix BM can be an organic insulating material to which a black pigment or a black dye is added.

As shown in FIG. 8A, a cover layer 118 can be disposed on the black matrix BM in the display area AA. The cover layer 118 can protect an device under the cover layer 118. For example, the cover layer 118 can be formed of an organic insulating material, but embodiments of the present disclosure are not limited thereto. For example, the cover layer 118 can be formed of a photo resist, polyimide (PI), a photo acryl-based material, or the like. The cover layer 118 can be referred to as an overcoating layer, an insulating layer, or the like.

A polarizing layer 280 can be disposed on the cover layer 118 via a first adhesive layer 291. A cover member 120 can be disposed on the polarizing layer 280 via a second adhesive layer 295. For example, the first adhesive layer 291 and the second adhesive layer 295 can include an optically clear adhesive (OCA), an optically clear resin (OCR), a pressure sensitive adhesive (PSA) or the like, but embodiments of the present disclosure are not limited thereto.

According to the present disclosure, the plurality of pad electrodes PE can be disposed on the third insulating layer 115c in the second non-display area NA2. For example, a portion of the plurality of pad electrodes PE can be exposed by the passivation layer 116. For example, the pad electrode PE can be electrically connected to the 2-4th connection line 122d through a contact hole of the third insulating layer 115c.

An adhesive film ACF can be disposed on the plurality of pad electrodes PE. The adhesive film ACF can be an adhesive layer in which conductive balls are distributed in an insulating material. When heat or pressure is applied to the adhesive film ACF, the conductive ball can be electrically connected to the pad electrode in a region to which heat or pressure is applied, and thus the conductive ball can have conductive characteristics. An adhesive film ACF can be disposed between the plurality of pad electrodes PE and the flexible circuit board (or flexible film) 170, so that a flexible circuit board (or flexible film) 170 can be attached to or bonded to the plurality of pad electrodes PE. For example, the adhesive film ACF can be an anisotropic conductive film (ACF).

The flexible circuit board (or flexible film) 170 can be disposed on the adhesive film ACF. The flexible circuit board (or flexible film) 170 can be electrically connected to the plurality of pad electrodes PE through the adhesive film ACF. Therefore, signals output from the flexible circuit board (or flexible film) 170 and the printed circuit board 160 can be transmitted to the pixel driving circuit PD of the display area AA through the pad electrode PE, the 2dth connection line 122d, the 2cth connection line 122c, the 2bth connection line 122b, and the 2ath connection line 122a.

Next, as described above, the second electrode CE2 includes main cathode electrodes CE2m connected to the light emitting devices ED and shield electrodes CE2s not connected to the light emitting devices ED.

In this case, referring to FIG. 8A and FIG. 9A, each of the main cathode electrodes CE2m is connected to the main contact electrode CCEm and the light emitting device ED. Accordingly, a cathode voltage or a touch driving signal supplied through the main cathode electrode line and the main contact electrode CCEm from the pixel driving circuit PD can be supplied to a light emitting device ED through the main cathode electrode CE2m.

Accordingly, light can be output from the light emitting device ED during the display period, and a touch can be sensed through the main cathode electrode CE2m during the touch sensing period.

In this case, a part of the main contact electrodes CCEm can be provided in the first optical layer 117a, and another part can be provided in the second optical layer 117b.

As shown in FIG. 9A, the contact hole for connecting the main contact electrode CCEm provided in the second optical layer 117b to the main cathode electrode CE2m can be filled with a black matrix BM. However, the contact hole for connecting the main contact electrode CCEm provided in the first optical layer 117a to the main cathode electrode CE2m may not be filled with a black matrix BM. In this case, a black matrix BM can be provided on the top surface of the third optical layer 117c covering the main cathode electrode CE2m.

However, when there is no third optical layer 117c, the contact hole for connecting the main contact electrode CCEm provided in the first optical layer 117a to the main cathode electrode CE2m can be filled with a black matrix BM.

When the first optical layer 117a and the second optical layer 117b are formed of the same material by the same process, all main cathode electrodes CE2m can have the same structure.

When the first optical layer 117a and the third optical layer 117c are provided, the shield electrodes CE2s can be provided on an upper end of the first optical layer 117a and can be covered by the third optical layer 117c.

However, the shield electrodes CE2s can be formed in the same structure as the main cathode electrodes CE2m.

The shield electrode CE2s can be provided between two main cathode electrodes CE2m adjacent to each other.

A separation area SA can be provided between the shield electrode CE2s and the main cathode electrode CE2m.

The black matrix BM can be disposed to cover a portion of the main cathode electrode CE2m and the shield electrode CE2s. That is, a black matrix BM is not disposed in an area of the main cathode electrode CE2m overlapping the light emitting device ED. Accordingly, light output from the light emitting device ED can be output to the outside through the cover layer 118.

Finally, referring to FIG. 9B, each of the shield electrodes CE2s is connected to the shield contact electrode CCEs. Therefore, a shield voltage or a touch driving signal supplied from the pixel driving circuit PD through the shield electrode line and the shield contact electrode CCEs can be supplied to the main cathode electrode CE2m.

In this case, a shield voltage (for example, a ground voltage) can be supplied to the shield electrode CE2s during the display period. Accordingly, when driving signals of various types and levels are supplied through various types of lines such as data lines and power lines provided in the display panel 100, the shield electrode CE2s can perform a function of blocking the driving signals. That is, a voltage of the shield electrode CE2s is not changed or shaken by the driving signals.

Therefore, distortion of the touch driving signal supplied to the main cathode electrodes CE2m and the shield electrode CE2s can be reduced during the touch sensing period that occurs after the display period.

Accordingly, a touch can be accurately determined, and touch sensitivity can be improved.

The shield electrodes CE2s can be provided in the first optical layer 117a, or as shown in FIG. 9b, can be provided in the second optical layer 117b.

In this case, the main cathode electrode CE2m can also be provided in the first optical layer 117a, or as shown in FIG. 9B, can be provided in the second optical layer 117b. Also, as shown in FIG. 9A, some main cathode electrodes CE2m can be provided in the first optical layer 117a, and some main cathode electrodes CE2m can be provided in the second optical layer 117a.

A contact hole for connecting the shield contact electrode CCEs provided in the second optical layer 117b to the shield electrode CE2s can be filled with a black matrix BM as shown in FIG. 9b.

However, when the third optical layer 117c is present, a contact hole for connecting the shield contact electrode CCEs provided in the second optical layer 117b to the shield electrode CE2s can be filled with the third optical layer 117c and a black matrix BM.

For example, in FIGS. 9A and 9B, a contact hole for connecting the main contact electrode CCEm to the main cathode electrode CE2m and a contact hole for connecting the shield contact electrode CCEs to the shield electrode CE2s can be filled with various materials depending on the structure of the optical layers 117a, 117b, and 117c.

In this case, the shield electrode CE2s can be provided between two main cathode electrodes CE2m adjacent to each other, as shown in FIG. 9B.

Also, a separation area SA can be provided between the shield electrode CE2s and the main cathode electrode CE2m.

The black matrix BM can be disposed to cover a portion of the main cathode electrode CE2m and the shield electrode CE2s.

In this case, as shown in FIGS. 7A to 9B, the light emitting devices DE can be connected to the first electrodes CE1 and the second electrode CE2. In particular, each of the light emitting devices DE can be connected to any one of the first electrodes CE1.

Also, each of the light emitting devices DE can be connected to any one of the main cathode electrodes CE2m.

FIG. 10 is an exemplary diagram illustrating a structure of a touch electrode part applied to a display apparatus according to an embodiment of the present disclosure. In the following descriptions, details that are the same as or similar to details described with reference to FIGS. 1 to 9B are omitted or briefly described.

The display apparatus according to an embodiment of the present disclosure can include a display panel 100 on which an imaged is displayed and a display driver for supplying image data and control signals to the pixel driving circuit PD in the display panel 100 during a display period and determining whether the display panel 100 is touched using touch sensing signals transmitted from pixel driving circuits PD provided in the display panel 100 during a touch sensing period.

Also, the display apparatus according to an embodiment of the present disclosure can further include a timing controller 300, a power supply part 500, a memory, etc., as described with reference to FIGS. 1 and 2, in addition to the display panel 100 and the touch determination part 200. In this case, the display driver 200 can be included in the timing controller 300.

The display driver 200 and the timing controller 300 can be provided on the printed circuit board 160.

As described above, the display panel 100 can include the substrate 110 including the display area AA and the non-display area NDA, the pixel driving circuits PD provided in the display area on the substrate 110, the insulating layer on the pixel driving circuits PD, the banks BNK on the insulating layer, the first electrodes CE1 connected to the pixel driving circuits PD, the light emitting devices ED provided on the first electrodes, and the second electrodes CE2 provided on the light emitting devices ED.

Here, the insulating layer can be formed as a single layer, but can include a plurality of layers. For example, the insulating layer can include the first insulating layer 115a, the second insulating layer 115b, and the third insulating layer 115c.

The first electrode CE1 can be provided in each of the banks BNK.

The light emitting device ED can be provided on the first electrode CE1.

The second electrode CE2 (in particular, the main cathode electrode CE2m) can be disposed on the light emitting device ED.

Each of the light emitting devices ED can be driven by any one of the pixel driving circuits PD.

Each of the pixel driving circuits PD can be connected to at least two light emitting devices ED to drive at least two light emitting devices ED.

Each of the second electrodes CE2 (in particular, the shield electrode CE2s) can be connected to at least two light emitting devices ED.

Some of the plurality of sub-pixels can be covered by the second electrode CE2. For example, the first light emitting device 130, the second light emitting device 140, and the third light emitting device 150 provided in the first sub-pixel SP1, the second sub-pixel SP2, and the third sub-pixel SP3 can be covered by one second electrode CE2.

However, as shown in FIGS. 7A and 7B, sub-pixels SP included in two or more pixels PX can be covered by one second electrode CE2.

At least two second electrodes CE2 can be connected to each of the pixel driving circuits PD. For example, when the first light emitting device 130, the second light emitting device 140, and the third light emitting device 150 provided in one pixel PX can be connected to one second electrode CE2. Also, when the pixel driving circuit PD drives at least two pixels PX, at least two second electrodes CE2 can be connected to the pixel driving circuit PD. For example, when the pixels PX arranged in a 16×16 form are connected to the pixel driving circuit PD, 16 second electrodes CE2 can be connected to the pixel driving circuit PD.

In this case, the display panel 100 can include a light emitting device part EDU including pixel driving circuits PD and light emitting devices ED, and a touch electrode part TEU including at least two second electrodes CE2.

For example, in the display panel 100 illustrated in FIG. 8A, the substrate 110, the buffer layers 111a and 111b, the adhesive layer 112, the pixel driving circuit PD, the protective layers 113a, 113b and 114, the insulating layers 115a, 115b, and 115c, the first connection line 121, the bank BNK, the first electrodes CE1, the light emitting devices CE1, and the optical layers 117a and 117b can be included in the light emitting device part EDU.

In addition, in the display panel 100 shown in FIG. 8A, the second electrodes CE2 can be included in the touch electrode part TEU.

Also, in the display panel 100 shown in FIG. 8A, the black matrix BM, the third optical layer 117c, and the cover layer 118 can be other components included in the display panel 100. However, hereinafter, for convenience of description, the black matrix BM, the third optical layer 117c, and the cover layer 118 can be included in the light emitting device part EDU.

To provide an additional description, as described with reference to FIG. 1, the display apparatus 1000 according to an embodiment of the present disclosure can include a display panel 100, a polarizing layer 280, an adhesive layer 290, a cover member 120, a support substrate 190, a flexible circuit board 170, and a printed circuit board 160, and the display panel 100 can include various layers as shown in FIG. 8A.

In this case, various layers included in the display panel 100 can be divided into the light emitting device part EDU and the touch electrode part TEU.

The light emitting device part EDU can include various layers as described above, and in particular, can include light emitting devices ED.

The touch electrode part TEU can include at least two second electrodes CE2.

In this case, the pixel driving circuits PD can be substantially included in the light emitting device part EDU, and can drive the first electrodes CE1 and the second electrodes CE2. However, for convenience of description, in FIG. 10, the pixel driving circuits PD are included in the touch electrode part TEU.

In the following description, the second electrodes CE2 controlled by one pixel driving circuit PD are referred to as a sub-touch electrode STE.

In addition, in the following description, a configuration including at least one sub-touch electrode STE and corresponding to one touch coordinate is referred to as a touch electrode TE.

For example, the sub-touch electrode STE can be connected to the pixel driving circuit PD, and the sub-touch electrode STE can include at least two second electrodes CE2. As described above, when the pixels PX arranged in the form of 16×16 are connected to the pixel driving circuit PD, the sub-touch electrode STE can include 16 second electrodes CE2.

Each of the second electrodes CE2 can include a plurality of main cathode electrodes CE2m and one shield electrode CE2s, as described above.

One pixel driving circuit PD controlling one sub-touch electrode STE can be connected to the display driver 200, as shown in FIG. 10.

Hereinafter, for convenience of description, a display apparatus according to the present disclosure will be described by taking as an example a touch electrode TE including four sub-touch electrodes STE provided along the first direction X and four sub-touch electrodes STE provided along the second direction Y, as shown in FIG. 10. However, depending on the structure or resolution of the display panel 100, the touch electrode TE provided on the left side of the display panel 100 or the touch electrode TE provided on the right side of the display panel 100 can include three sub-touch electrodes STE provided along the first direction X and four sub-touch electrodes STE provided along the second direction Y. For example, in the display panel 100, each of the touch electrodes TE provided on the right side or the left side of the display panel 100 can include three sub-touch electrodes STE provided along the first direction X and four sub-touch electrodes STE provided along the second direction Y.

To provide an additional description, in the following description, the touch electrode TE can include 16 sub-touch electrodes STE. However, the number of sub-touch electrodes STE included in the touch electrode TE can be variously changed.

In this case, the display driver 200 can include a data driver that generates image data to be supplied to the pixel driving circuit PD and a touch driver for sensing a touch.

For example, the display driver 200 can generate image data to be supplied to the pixel driving circuit PD and supply the image data to the pixel driving circuit PD.

To this end, each of the pixel driving circuits PD corresponding to all the sub-touch electrodes STE included in the touch electrode part TEU can be connected to the display driver 200 through at least one line.

In this case, the power required by the pixel driving circuit PD can be transmitted from the power supply part 500 to the pixel driving circuit PD through the display driver 200, or can be directly transmitted from the power supply part 500 to the pixel driving circuit PD.

Furthermore, the display driver 200 can supply a touch driving signal to the pixel driving circuit PD and sense the presence or absence of a touch on the display panel 100 by using a touch sensing signal received from the pixel driving circuit PD.

However, the touch driving signal can be generated in the pixel driving circuit PD to be supplied to the touch electrodes TE, and the display driver 200 can sensing a touch on the display panel 100 by using a touch sensing signal received from the pixel driving circuit PD.

In this case, the touch coordinates can be determined by the display driver 200, or can be determined by the timing controller 300 or the external system 900.

That is, in a display apparatus according to an embodiment of the present disclosure, a structure and method for sensing a touch can be variously changed.

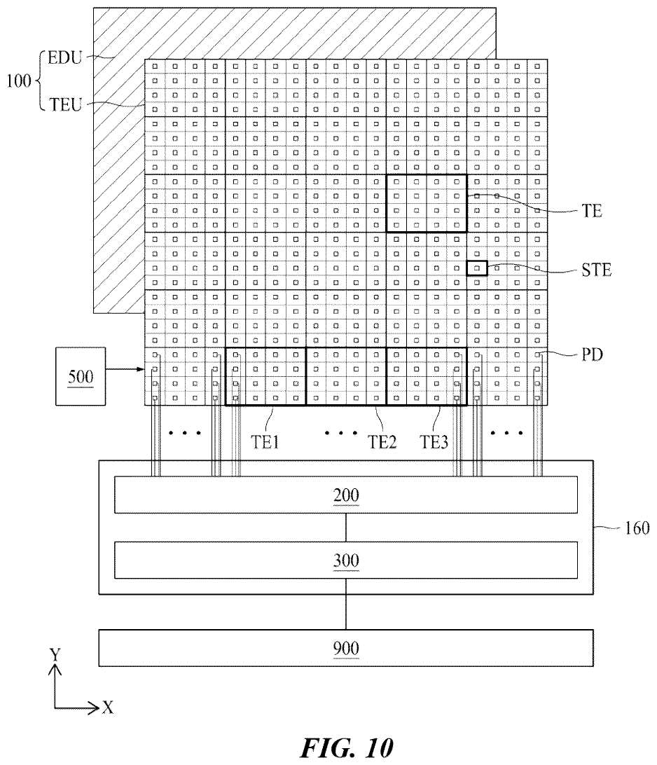

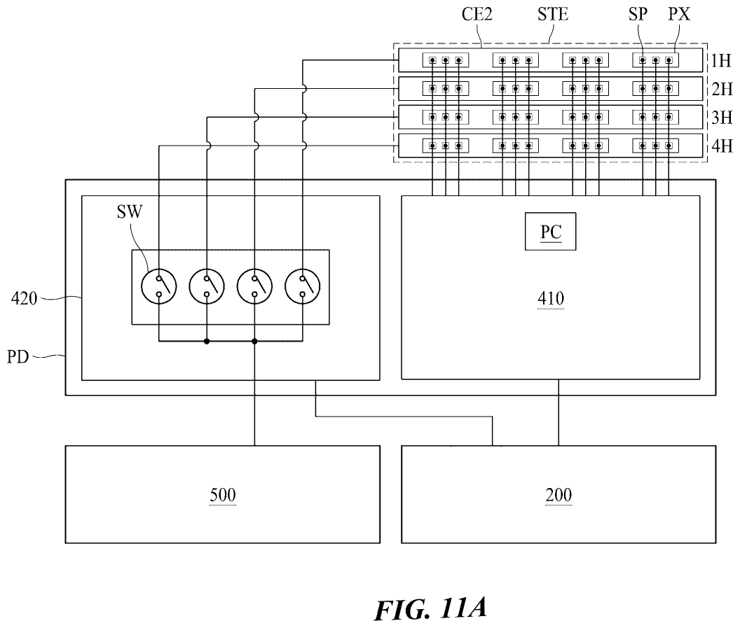

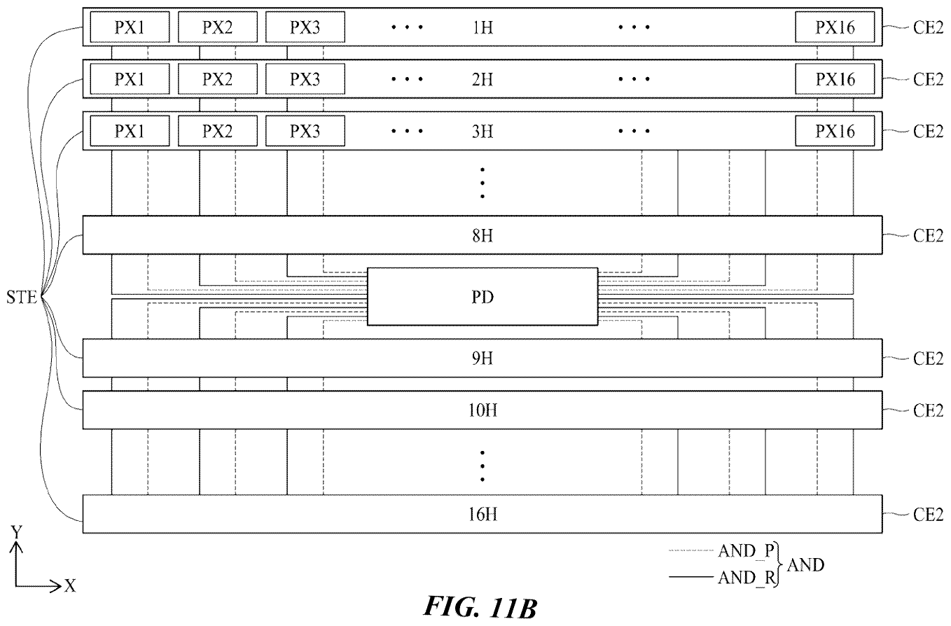

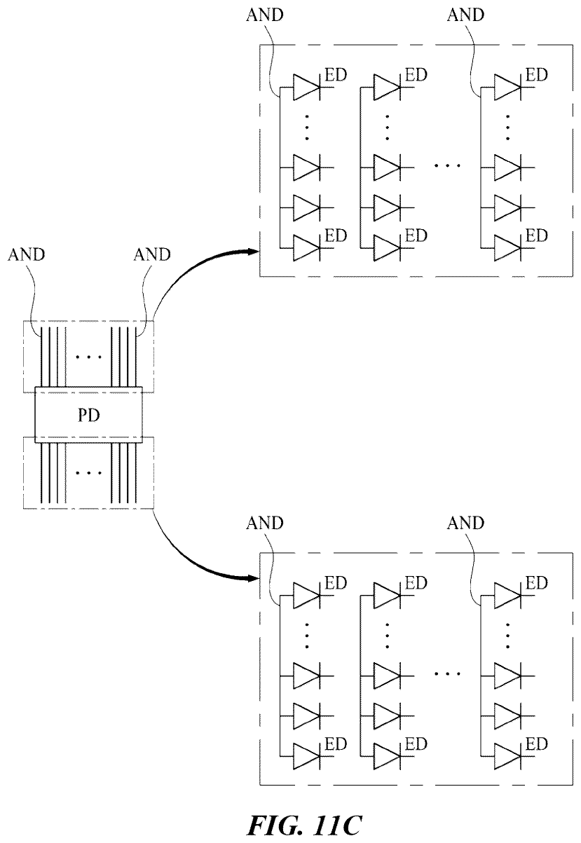

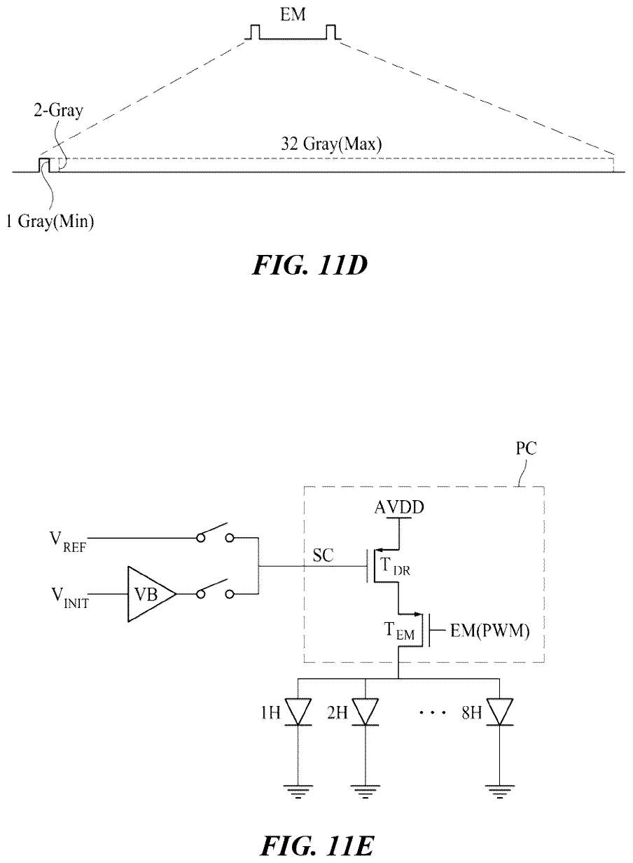

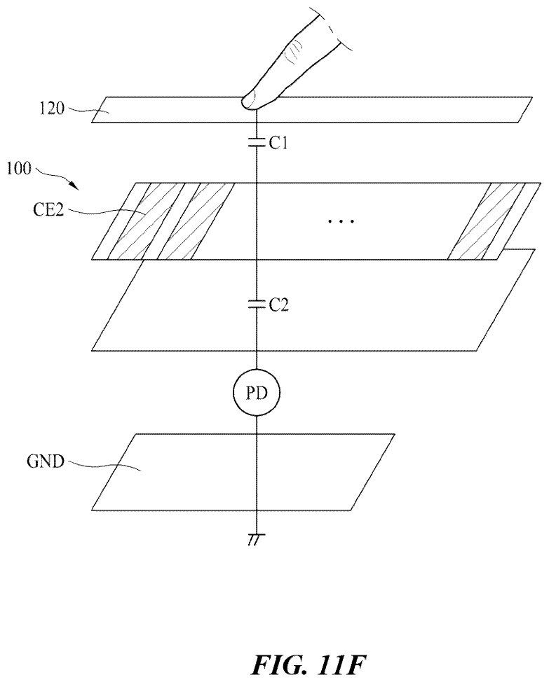

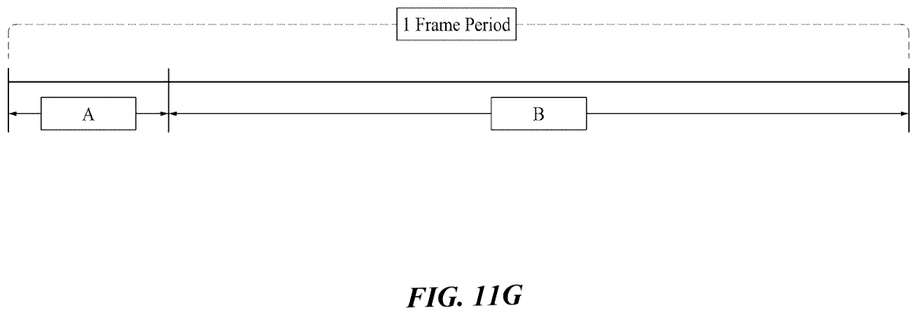

FIG. 11A is an exemplary diagram illustrating structures of a sub-touch electrode and a pixel driving circuit applied to a display apparatus according to an embodiment of the present disclosure, FIG. 11B is an exemplary diagram illustrating a connection structure of a sub-touch electrode and a pixel driving circuit applied to a display apparatus according to an embodiment of the present disclosure, and FIG. 11C is an exemplary diagram illustrating a connection relationship between a pixel driving circuit and light emitting devices applied to a display apparatus according to an embodiment of the present disclosure.

In the following descriptions, details that are the same as or similar to details described with reference to FIGS. 1 to 10 will be omitted or briefly described. In this case, as described above, each of the second electrodes CE2 can include main cathode electrodes CE2m and shield electrodes CE2s. In this case, in the display period, a cathode voltage is supplied to the main cathode electrodes CE2m and a shield voltage (e.g., a ground voltage) different from the cathode voltage is supplied to the shield electrodes CE2s, and in the touch sensing period, a touch driving signal is supplied to the main cathode electrodes CE2m and the shield electrodes CE2s.

However, in FIG. 11A, for convenience of description, each of the second electrodes CE2 is illustrated in the form of a single plate, and a control switch SW for switching the cathode voltage and the touch driving signal is connected to the second electrode CE2.

In this case, each of the control switches SW can be changed and specified in various forms in order to supply a cathode voltage to the main cathode electrodes CE2m and a shield voltage to the shield electrodes CE2s during the display period, and supply a touch driving signal to the main cathode electrodes CE2m and shield electrodes CE2s during the touch sensing period. Each of the control switches SW can be driven by a control signal transmitted from the display driver 200 or the timing controller 300.

As shown in FIG. 11A, the pixel driving circuit PD can include a sub-pixel driving part 410 for supplying anode voltages to anode electrodes 134 provided in the sub-pixels SP and a touch control part 420 for supplying a cathode voltage or a touch driving signal to a second electrode CE2 shared in at least two sub-pixels SP.

As described above, the second electrodes CE2 controlled by one pixel driving circuit PD are referred to as sub-touch electrode STE.

The sub-touch electrode STE can include at least two second electrode CE2.

As described above, at least two light emitting devices ED can be connected to one pixel driving circuit PD. In addition, one second electrode CE2 can be connected to at least two light emitting devices ED.

Hereinafter, for convenience of description, a display apparatus including a pixel driving circuit PD to which 16 pixels PX having a 4×4 shape are connected, as shown in FIG. 11A, is described as an example of a display apparatus according to an embodiment of the present disclosure. In addition, in the display apparatus shown in FIG. 11A, pixels PX arranged in a 4×4 shape are connected to the pixel driving circuit PD, but in the display apparatus according to an embodiment of the present disclosure, pixels PX arranged in a 4N×4M (N and M are natural numbers) form can be connected to the pixel driving circuit PD. For example, in FIG. 11B, pixels PX arranged in a 16×16 shape are connected to the pixel driving circuit PD.

For example, as shown in FIG. 11A, the pixel driving circuit PD can be connected to four pixels PX provided along the first direction X and four pixels PX provided along the second direction Y.

In this case, one second electrode CE2 controlled by the pixel driving circuit PD can be connected to the light emitting devices DE provided in at least two sub-pixels SP.

In particular, the second electrode CE2 can be connected to at least two light emitting devices DE provided along the first direction X of the display panel 100, and as shown in FIGS. 7A and 7B, the at least two second electrodes CE2 provided along the second direction Y can be separated from each other.

When four pixels PX are provided along the first direction X, and one pixel PX includes three sub-pixels SP, 12 sub-pixels PX can be provided along the first direction X.

In this case, when the second electrode CE2 provided along the first direction X is shared by the two sub-pixels SP, six second electrodes CE2 can be provided along the first direction X.

Accordingly, one pixel driving circuit PD can be connected to 24 (=6×4) second electrodes CE2.

However, hereinafter, for convenience of description, as shown in FIG. 11A, the display apparatus according to an embodiment of the present description will be described by taking as an example a display apparatus in which four pixels PX provided along the first direction X are connected to one second electrode CE2.

In this case, the pixel driving circuit PD can be connected to the four second electrodes CE2.

For example, for convenience of description, the display apparatus according to an embodiment of the present disclosure is described using a pixel driving circuit PD to which 16 pixels PX having a 4×4 shape are connected, a second electrode CE2 connected to four pixels PX along the first direction X, and four second electrodes CE2 along the second direction Y, as shown in FIG. 11A.

First, the structure of the display panel 100, the structure of the pixel driving circuit PD, and the method of driving the pixel driving circuit PD are briefly described with reference to FIG. 11A.

Hereinafter, as shown in FIGS. 4 and 11A, a circuit provided in the pixel driving circuit PD for driving at least one light emitting device ED is referred to as a pixel circuit PC. For example, the pixel circuit PC can include a driving transistor TDR and a light emitting transistor TEM, as shown in FIG. 4. In this case, a scan signal SC capable of turning on the driving transistor TDR can be supplied to a gate of the driving transistor TDR. The scan signal SC can be a direct current power source capable of continuously turning on the driving transistor TDR. For example, a fixed reference voltage V ref can be supplied to the gate of the driving transistor TDR for each frame.

A light emitting signal EM can be supplied to the gate of the light emitting transistor TEM. The light emitting signal EM can be a pulse width modulation (PWM) signal. The amount of current supplied to the light emitting device ED can be controlled by the light emitting signal EM, and thus, light having various brightness can be output from the light emitting device ED. At least one pixel circuit PC can be provided in the sub-pixel driving part 410.

In this case, a high potential power supply voltage VDD can be supplied to the first electrode of the driving transistor TDR provided in the pixel circuit PC. The high potential power supply voltage VDD can be supplied from the power supply part provided outside the pixel driving circuit PD.

The scan signal SC and the light emitting signal EM can be transmitted from a control signal generation part provided outside the pixel driving circuit PD. For example, the scan signal SC and the light emitting signal EM can be transmitted from a control signal generation part included in the timing controller 300.

For example, as shown in FIG. 11A, when four pixels PX connected to the pixel driving circuit PD are provided in one row extending along the first direction X, 16 pixels PX can be provided in four rows 1H, 2H, 3H, and 4H.

To provide an additional description, each of the four rows can be provided along the first direction X, and the four rows can be spaced apart along the second direction Y.

In this case, in order to output light from the light emitting devices ED provided in the first row 1H, light emitting signals EM and scan signals can be supplied to pixel circuits PC connected to the light emitting devices ED provided in the first row 1H.

As described above, the scan signal SC can be a direct current (DC) power source capable of continuously turning on the driving transistor TDR, and the light emitting signal EM can be a pulse width modulation (PWM) signal.

The light emitting transistor TEM can be turned on by the scan signal SC, and thus, the high potential power supply voltage VDD can be supplied to the anode electrode 134 of the light emitting device ED through the driving transistor TDR, the light emitting transistor TEM, and the first electrode CE1.

In this case, as described above, the light emitting signal EM applied to the gate electrode of the light emitting transistor TEM can be a pulse width modulation (PWM) signal, and the pulse width of the light emitting signals EM supplied to the pixel circuits PC connected to the anode electrodes 134 of the light emitting devices ED provided in the first row 1H can be variously set depending on the brightness of light output from the light emitting devices ED.

For example, the pulse width of the light emitting signal EM supplied to the pixel circuit PC connected to the light emitting device outputting high-brightness light can be greater than the pulse width of the light emitting signal EM supplied to the pixel circuit PC connected to the light emitting device outputting low-brightness light.

In this case, when a high-level pulse is supplied to the gate of the light emitting transistor TEM, the light emitting transistor TEM can be turned on.

When the period in which the light emitting transistor TEM is turned on increases, the amount of current supplied to the light emitting device ED through the light emitting transistor TEM can increase. The luminance of the light emitting device ED can vary based on the magnitude of the current flowing to the light emitting device ED.

Therefore, as the pulse width of the light emitting signal EM increases, the luminance of light output from the light emitting device ED can increase.

Also, when the pulse width of the light emitting signal EM supplied to the pixel circuit PC connected to the light emitting device outputting high-brightness light and the pulse width of the light emitting signal EM supplied to the pixel circuit PC connected to the light emitting device outputting low-brightness light are the same, the number of pulses of the light emitting signal EM supplied to the pixel circuit PC connected to the light emitting device outputting high-brightness light can be greater than the number of pulses of the light emitting signal EM supplied to the pixel circuit PC connected to the light emitting device outputting low-brightness light. For example, the frequency of the light emitting signal EM supplied to the pixel circuit PC connected to the light emitting device outputting high-brightness light can be greater than the frequency of the light emitting signal EM supplied to the pixel circuit PC connected to the light emitting device outputting low-brightness light.

When the frequency increases, the number of pulses increases. When the number of pulses supplied to the light emitting transistor TEM increases, the number of times the light emitting transistor TEM is turned on increases. When the number of times the light emitting transistor TEM is turned on increases, the amount of current flowing to the light emitting device ED through the light emitting transistor TEM can increase.

As described above, because the luminance of the light emitting device ED can be changed depending on the magnitude of the current flowing to the light emitting device ED, as the frequency of the light emitting signal EM increases or the number of pulses of the light emitting signal EM increases, the luminance of light output from the light emitting device ED can increase.

For example, the timing controller 300 can supply light emitting signals EM with different frequencies or different pulse widths to the light emitting transistor TEM provided in the pixel circuit PC.

Accordingly, light having different luminance can be output from the light emitting devices ED connected to the pixel driving circuit PD.

When the scan signal SC is supplied to the driving transistor TDR, the touch control part 420 can supply cathode voltages to the main cathode electrodes CE2 and shield voltages to the shield electrodes CE2s.

For example, as shown in FIG. 11A, when 16 pixels PX having a 4×4 shape are connected to the pixel driving circuit PD and one second electrode CE2 is connected to four pixels PX provided along the first direction X, 16 pixels PX can be provided in four rows 1H, 2H, 3H, and 4H, and the four rows 1H, 2H, 3H, and 4H can be spaced apart from each other along the second direction Y.

In this case, four pixels PX provided in each of the four rows 1H, 2H, 3H and 4H are connected to one second electrode CE2. Accordingly, four second electrodes CE2 are provided in the display panel 100 for driving the 16 pixels PX.

The four second electrodes CE2 are connected to one pixel driving circuit PD. The four second electrodes CE2 connected to one pixel driving circuit PD are referred to as sub-touch electrodes STE. For example, the sub-touch electrode STE can include four second electrodes CE2.

To provide an additional description, at least one second electrode CE2 connected to the pixel driving circuit PD can be provided along the first direction X or row of the display panel 100, and at least two light emitting devices ED connected to the second electrode CE2 can be provided in a row along the first direction X or row.

In the above example, three sub-pixels SP are provided in each of the four pixels PX provided in the first row 1H.

Accordingly, when anode voltages are supplied from the 12 pixel circuits PC connected to the 12 sub-pixels SP provided in the first row 1H to the 12 anode electrodes 134 provided in the 12 sub-pixels SP, the touch control part 420 can supply a cathode voltage to the main cathode electrodes CE2m of the second electrode CE2 provided in the first row 1H and supply a shield voltage to the shield electrode CE2s of the second electrode CE2 provided in the first row. Accordingly, light can be output from the sub-pixels SP provided in the first row 1H.

This operation can be concurrently (or in some embodiments, simultaneously) performed in sub-pixels SP provided in the first row 1H and connected to other pixel driving circuits PD. Accordingly, light can be concurrently (or in some embodiments, simultaneously) output from all sub-pixels SP provided in the first row 1H of the display panel 100, and a shield voltage can be supplied to the shield electrodes CE2s provided in an area that does not overlap the light emitting devices in the first row 1H.

Also, when anode voltages are supplied from the 12 pixel circuits PC connected to the 12 sub-pixels SP provided in the second row 2H to the 12 anode electrodes 134 provided in the 12 sub-pixels SP, the touch control part 420 can supply a cathode voltage to the main cathode electrodes CE2m of the second electrode CE2 provided in the second row 2H, and supply a shield voltage to the shield electrode CE2s of the second electrode CE2 provide in the second row 2H. Accordingly, light can be output from the sub-pixels SP provided in the second row 2H.

This operation can be concurrently (or in some embodiments, simultaneously) performed in sub-pixels SP provided in the second row 2H and connected to other pixel driving circuits PD. Accordingly, light can be concurrently (or in some embodiments, simultaneously) output from all sub-pixels SP provided in the second row 2H of the display panel 100, and a shield voltage can be supplied to the shield electrodes CE2s provided in an area that does not overlap the light emitting devices in the second row 2H.

By the above-described operations, light can be sequentially output from sub-pixels SP provided in all rows of the display panel 100, and thus, one image can be displayed through the display panel 100.

The sub-pixels SP can be individually driven by the structure and driving method as described above.

In order to perform the above operation, the touch control part 420 includes control switches SW connected to the second electrodes CE2, as shown in FIG. 11A.

In this case, in order to supply a cathode voltage to the main cathode electrodes CE2m and a shield voltage to the shield electrodes CE2s in the display period, and in order to supply a touch driving signal to the main cathode electrodes CE2m and the shield electrodes CE2s in the touch sensing period, each of the control switches SW can be changed and specified in various forms. That is, a structure of the control switch SW for performing the function as described above can be variously changed, and thus, a detailed description of the structure of the control switch SW is omitted.

In the above example, one sub-touch electrode STE includes four second electrodes CE2, and the four second electrodes CE2 are connected to one pixel driving circuit PD.

In this case, the touch control part 420 can include four control switches SW. Each of the four control switches SW is connected to the second electrode CE2. More specifically, each of the four control switches SW is connected to the main contact electrodes CCEm connected to the second electrode CE2 and at least one shield contact electrode CCEs.

During a display period in which an image is displayed on the display panel 100, the control switch SW can supply a cathode voltage to the main contact electrodes CCEm connected to the second electrode CE2, and can supply a shield voltage to at least one shield contact electrode CCEs connected to the second electrode CE2.

In this case, the four control switches SW can be sequentially driven.

For example, the first control switch SW can be driven to supply a cathode voltage to the main contact electrodes CCEm provided in the first row 1H, and a shield voltage to the shield contact electrodes CCEs provided in the first row 1H.

After that, a second control switch SW can be driven to supply a cathode voltage to the main contact electrodes CCEm provided in the second row 2H and a shield voltage to the shield contact electrodes CCEs provided in the second row 2H.

After that, a third control switch SW and a fourth control switch SW can be sequentially driven in the same manner as the first control switch SW and the second control switch SW.

Also, during the touch sensing period in which a touch is sensed on the display panel 100, the control switches SW can be concurrently (or in some embodiments, simultaneously) driven to supply a touch driving signal to the main contact electrodes CCEm and shield contact electrodes provided in the first to fourth rows 1H to 4H.

Each of the cathode voltage, the shield voltage, and the touch driving signal can be transmitted from the power supply part 500 or the display driver 200 to the control switch SW, or can be directly generated in the touch control part 420.

The display period for displaying an image and the touch sensing period for sensing a touch can be implemented in a time division method.

For example, each of the pixel driving circuits PD can supply a touch driving signal to all the second electrodes CE2 connected to the pixel driving circuit PD during the touch sensing period.

In the above example, one second electrode CE2 is provided in one row, and four second electrodes CE2 are provided in four rows. Accordingly, the control switch SW can supply a touch driving signal to all of the four second electrodes CE2.

When two or more second electrodes CE2 are provided in one row, the control switch SW can supply a touch driving signal to all of the two or more second electrodes CE2 provided in one row.

When the touch driving signal is concurrently (or in some embodiments, simultaneously) supplied to the four second electrodes CE2 provided in the four rows 1H, 2H, 3H, and 4H, a touch sensing signal can be generated in the four rows.

The touch sensing signals generated in the four rows can be transmitted to the display driver 200 from the touch control part 420 or transmitted to the display driver 200 through the sub-pixel driving part 410.

Second, another structure of the display panel 100 will be briefly described with reference to FIGS. 11B and 11C.

As described above, in the display apparatus according to an embodiment of the present disclosure, pixels PX arranged in a 4×4 form as illustrated in FIG. 11A can be connected to the pixel driving circuit PD, pixels PX arranged in a 16×16 form as illustrated in FIG. 11B can be connected to the pixel driving circuit PD, or pixels PX arranged in various forms can be connected to the pixel driving circuit PD. Hereinafter, a structure of a display panel 100 applied to a display apparatus according to an embodiment of the present disclosure will be described with reference to FIGS. 11B and 11C. In the following descriptions, details that are the same as or similar to details described with reference to FIGS. 1 to 11A will be omitted or briefly described.

In the display apparatus according to another embodiment of the present disclosure, a pixel driving circuit PD and pixels PX1 to PX16 including light emitting devices ED electrically connected to the pixel driving circuit PD can be provided.

For example, the first to sixteenth pixels PX1 to PX16 can be arranged along the first direction X. One pixel PX can include a red sub-pixel, a green sub-pixel, and a blue sub-pixel SP.

A light emitting device ED can be disposed in the sub-pixel SP. At least one light emitting device ED can be disposed in one sub-pixel SP. For example, two light emitting devices can be disposed in one sub-pixel. One of the two light emitting devices can be a main light emitting device, and the other can be a redundancy light emitting device. The light emitting device ED can be a micro LED.

A red sub-pixel, a green sub-pixel, and a blue sub-pixel can be repeatedly disposed along the first direction X.

Sub-pixels SP that output light of the same color can be disposed along the second direction Y. For example, along the second direction Y, sub-pixels SP that output light of any one color of red, green, and blue can be disposed. The sub-pixels SP emitting the same color can be electrically connected through one first electrode line AND, as shown in FIG. 11C. The first electrode line AND can be connected to the first electrodes CE1.

The first electrode line AND can include a first line AND_P and a second line AND_R. The first line AND_P and the second line AND_R can be disposed to be spaced apart from each other in the first direction X. The first line AND_P can be connected to the main light emitting device, and the second line AND_P can be connected to the redundancy light emitting device.

Each of the second electrodes CE2 can extend in the first direction X, as shown in FIG. 11B. Also, each of the second electrodes CE2 can be arranged to be spaced apart from each other along the second direction Y. Accordingly, each of the second electrodes CE2 can be connected to the first to sixteenth pixels PX1 to PX16 disposed in each of the rows 1H to 16H. In this case, each of the second electrodes CE2 can include main cathode electrodes CE2m and a shield electrode CE2s. Each of the main cathode electrodes CE2m is connected to the light emitting device ED, and the shield electrode CE2s is not connected to the light emitting device ED. For example, the shield electrode CE2s is electrically isolated from the main cathode electrodes CE2m.

The pixel driving circuit PD can be connected to the pixels PX1 to PX16 through the first electrodes CE1 and the main cathode electrodes CE2m. Accordingly, the pixel driving circuit PD can drive the light emitting devices ED arranged in the first to sixteenth rows 1H to 16H.

To provide an additional description, the pixel driving circuit PD can be electrically connected to the light emitting devices arranged in the first to 16th rows 1H to 16H through the first electrodes CE1 and the main cathode electrodes CE2m, and the pixel driving circuit PD can supply the control signal and power to the light emitting devices ED to control the light emitting operation of the light emitting devices ED.

In this case, the second electrodes CE2 can be connected to the pixels PX and the pixel driving circuit PD in the form shown in FIG. 11B, the first electrodes CE1 provided in the pixels PX can be connected to the first electrode lines AND in the form shown in FIG. 11C, and the first electrodes CE1 can be connected to the pixel driving circuit PD through the first electrode lines AND.

For example, in the light emitting device part EDU, as shown in FIG. 11C, first electrode lines AND can be disposed on the upper and lower sides of the pixel driving circuit PD, respectively.

As shown in FIG. 11C, one first electrode line AND among the first electrode lines AND can connect the first electrodes CE1 of the light emitting devices ED adjacent to each other in the vertical direction (for example, the second direction Y) among the light emitting devices ED.

In this case, a pixel circuit PC can be connected to each of the first electrode lines AND. However, the pixel circuit PC can be connected to at least two first electrode lines AND. In this case, the anode voltage can be sequentially supplied to at least two first electrode lines AND.

Hereinafter, the basic driving method of the display apparatus according to the present disclosure in the display period in which the image is displayed will be briefly described.

FIG. 11D is an exemplary diagram illustrating a light emitting signal EM applied to a display apparatus according to an embodiment of the present disclosure, and FIG. 11E is an exemplary diagram illustrating a pixel circuit PC applied to a display apparatus according to an embodiment of the present disclosure.

As described above, the pixel driving circuit PD can control the light emitting operation of the light emitting device ED by using the pulse width of the light emitting signal EM.

For example, as shown in FIG. 11D, the pixel driving circuit PD can adjust the pulse width of the light emitting signal EM, and thus, light corresponding to 1 Gray to 32 Gray can be output through the light emitting device ED.

The pixel driving circuit PD can supply a light emitting signal EM having a pulse width adjusted based on gray to a gate electrode of the light emitting transistor TEM.

In this case, a fixed light emitting current can be applied to the light emitting device ED through the light emitting transistor TEM, and thus, the light emitting device ED can output light.

For example, when eight light emitting devices ED are connected to one first electrode line AND, the eight light emitting devices ED can output light by constant current having the same current value.

In this case, in a typical organic light emitting display apparatus, the amount of current flowing to the light emitting device is different because the voltage applied to the gate electrode of the driving transistor varies from one light emitting device to another, and the time for which the current flows to the light emitting devices is the same.

However, in the display apparatus according to an embodiment of the present disclosure, the amount of current flowing to the light emitting devices ED is the same, and the time for which the current flows is different for each light emitting device. That is, the time for which the current flows through the light emitting device can be adjusted by the pulse width of the light emitting signal (PWM signal) EM.

For example, the pixel circuit PC, as shown in FIGS. 4 and 11E, includes a driving transistor TDR and a light emitting transistor TEM, and is connected to light emitting devices. Reference numerals 1H, 2H, and 8H shown in FIG. 11E refer to light emitting devices ED provided in the first column 1H, the second column 2H, and the eighth column 8H shown in FIG. 11B.

A high potential voltage AVDD can be applied to the first electrode of the driving transistor TDR, a light emitting transistor TEM can be connected to the second electrode of the driving transistor TDR, and a reference voltage VREF or initialization voltage VINT can be applied to the gate electrode of the driving transistor TDR. The reference voltage VREF or the initialization voltage VINT can be a scan signal SC.

For example, a reference voltage VREF can be applied to the gate electrode of the driving transistor TDR through a switching means, or an initialization voltage VINT can be applied to the gate electrode of the driving transistor TDR through a voltage buffer (V B) and a switching means.

A driving transistor TDR can be connected to the first electrode of the light emitting transistor TEM, light emitting devices can be connected to the second electrode of the light emitting transistor TEM, and a light emitting signal EM can be applied to the gate electrode of the light emitting transistor TEM.

Hereinafter, a display period in which an image is displayed and a touch sensing period in which a touch is sensed will be briefly described with reference to FIGS. 11F and 11G.

FIG. 11F is an exemplary diagram illustrating a touch sensing method in a display apparatus according to an embodiment of the present disclosure, and FIG. 11G is an exemplary diagram illustrating one frame period applied to a display apparatus according to an embodiment of the present disclosure.

In the display apparatus according to an embodiment of the present disclosure, the second electrodes CE2 can be used as a touch electrode TE, and this structure is referred to as an in-cell touch structure. Because a separate touch electrode is not provided in the display apparatus according to an embodiment of the present disclosure, the thickness of the display panel can be reduced.

In the touch sensing period, a touch driving signal is supplied to the second electrodes CE2.

For example, when the cover member 120 is touched by the user, the first capacitance C1 between the second electrodes CE2 and the cover member 120 which are provided on the display panel 100 and the second capacitance C2 between the second electrodes CE2 and the signal lines can be changed, as shown in FIG. 11F.

The touch sensing signal generated by the change of the first capacitance C1 and the second capacitance C2 can be transmitted to the pixel driving circuit PD through the second electrodes CE2. In this case, the pixel driving circuit PD can be connected to the ground part GND.

The touch sensing signals transmitted to the pixel driving circuit PD can be transmitted to the display driver 200, and the display driver 200 can determine whether there is a touch on the touch electrode TE by using the touch sensing signals transmitted from the at least one pixel driving circuit PD.

One frame period (1Frame Period) can mean a period in which one image is displayed through the display panel 100. As shown in FIG. 11G, one frame period (1Frame Period) can include a touch sensing period A and a display period B.

In one frame period, the touch sensing period A and the display period B can be different. For example, the touch sensing period A can be shorter than the display period B.

Also, the touch sensing period A and the display period B can be repeated multiple times in one frame period.

That is, in a display apparatus according to an embodiment of the present disclosure, a method and structure for sensing a touch can be variously changed.

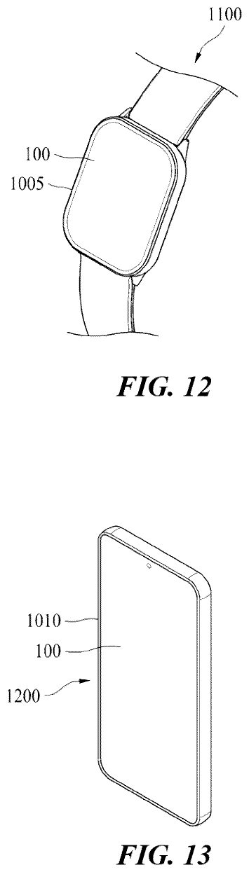

FIGS. 12 to 15 are diagrams illustrating electronic devices to which a display apparatus according to embodiments of the present disclosure is applied.

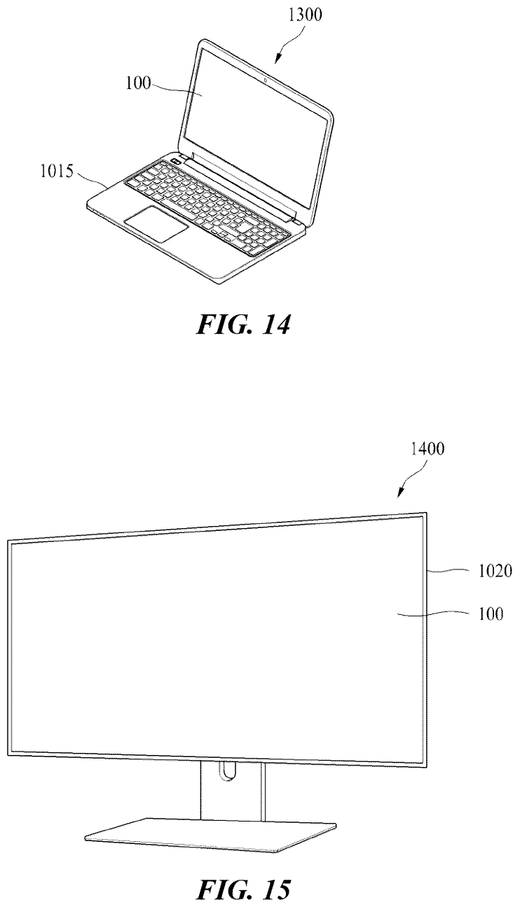

Referring to FIGS. 12 to 15, the display apparatus according to embodiments of the present disclosure can be included in various electronic devices. For example, various electronic devices can be a wearable device 1100 as shown in FIG. 12 a mobile device 1200 as shown in FIG. 13, a laptop 1300 as shown in FIG. 14, and a monitor or TV 1400 as shown in FIG. 15. However, embodiments of the present disclosure are not limited thereto.

Each of the wearable device 1100, the mobile device 1200, the laptop 1300, and the monitor or TV 1400 can include a case part 1005, 1010, 1015, and 1020, and a display panel 100 and a display apparatus 1000 as described above.

A display apparatus according to an embodiment of the present disclosure includes a substrate including a display area and a non-display area, a pixel driving circuits provided in the display area, first electrodes connected to the pixel driving circuit, light emitting devices electrically connected to the first electrodes, and a second electrode connected to the light emitting devices, wherein each of the pixel driving circuits is connected to light emitting devices provided in at least two sub-pixels, the second electrode includes main cathode electrodes connected to light emitting devices and a shield electrode between the main cathode electrodes and separated from the main cathode electrodes, and each of the light emitting devices is connected to any one of the first electrodes.

A main cathode electrode is connected to a main light emitting device and a redundancy light emitting device included in a sub-pixel.

At least two second electrodes connected to any one pixel driving circuit are used as one touch electrode.

Each of the at least two second electrodes extends along a first direction of the substrate, and the at least two second electrodes are provided along a second direction different from the first direction.

When a cathode voltage is supplied to any one of the at least two second electrodes, light is output from light emitting devices connected to a second electrode to which the cathode voltage is supplied.

A touch driving signal is concurrently (or in some embodiments, simultaneously) supplied to the at least two second electrodes when the at least two second electrodes are used as one touch electrode.

The main cathode electrodes are connected to the light emitting devices, and the shield electrode is not connected to the light emitting devices.

A main cathode electrode is provided in a form of an island in an area corresponding to a light emitting device, and the shield electrode is provided outside the main cathode electrode.

The shield electrode extends along a first direction of the substrate, a through hole through which the light emitting device is exposed is provided in an area, which corresponds to a light emitting device, of the shield electrodes, and the main cathode electrode is provided in a form of an island in the through hole.

During a display period when an image is displayed, a cathode voltage is supplied to the main cathode electrodes and a shield voltage different from the cathode voltage is supplied to the shield electrode, and during a touch period in which a touch is sensed, a touch driving signal is supplied to the main cathode electrodes and the shield electrode.

Each of the main cathode electrodes is connected to a main cathode electrode line through a main contact electrode, and the shield electrode is connected to a shield electrode line through at least one shield contact electrode.

The main cathode electrode line and the shield electrode line are connected to a pixel driving circuit.

During a display period when an image is displayed, a cathode voltage is supplied from the pixel driving circuit to a main cathode electrode through the main cathode electrode line and a shield voltage different from the cathode voltage is supplied from the pixel driving circuit to the shield electrode through the shield electrode line, and during a touch period in which a touch is sensed, a touch driving signal is supplied from the pixel driving circuit to the main cathode electrode and the shield electrode through the main cathode electrode line and the shield electrode line.

A separation area in which the main cathode electrode and the shield electrode are spaced apart from each other is provided outside the main cathode electrode.

The separation area surrounds an outside of the main cathode electrode in a ring shape.

The main cathode electrodes are spaced apart from each other with the shield electrode interposed therebetween.

Each of the light emitting devices is connected to any one of the main cathode electrodes.

The display apparatus according to an embodiment of the present disclosure can be applied to a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), PDA (personal digital assistant), an MP3 player, a mobile medical device, a desktop PC, a laptop PC, a netbook computer, a workstation, a navigation, a vehicle display, a theater display, a television, a wall paper device, a signage device, a game device, a laptop, a game device, a monitor, a camera, a camcorder or a home appliance.

According to the present disclosure, a second electrode used as a touch electrode and a cathode electrode can be divided into main cathode electrodes provided in sub-pixels and shield electrode provided between the main cathode electrodes, the main cathode electrodes can be separated from the shield electrode, and the main cathode electrodes can be spaced apart from each other with the shield electrode interposed therebetween.

In this case, during a display period when an image is displayed, a cathode voltage can be supplied to the main cathode electrodes and a voltage different from the cathode voltage can be supplied to the shield electrode, and during a touch sensing period when a touch is sensed, a touch driving signal can be supplied to the main cathode electrodes and shield electrodes.

Accordingly, when driving signals of various types and levels are supplied through various types of lines such as data lines and power lines during the display period, the shield electrode can perform a function of blocking the driving signals. That is, the voltage of the shield electrode is not changed by the driving signals.

Therefore, distortion of the touch driving signal supplied to the main cathode electrodes and the shield electrode during the touch sensing period can be reduced.

Accordingly, a touch can be accurately determined, and touch sensitivity can be improved.

Also, according to the present disclosure, a display apparatus having high efficiency, high luminance and low power characteristics can be provided, and accordingly, a display apparatus capable of implementing ESG (Environment/Social/Governance) can be provided.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a substrate including a display area and a non-display area;
a pixel driving circuits provided in the display area;
first electrodes connected to the pixel driving circuit;
light emitting devices connected to the first electrodes; and
a second electrode connected to the light emitting devices,
wherein each of the pixel driving circuits is connected to light emitting devices provided in at least two sub-pixels,
wherein the second electrode comprises:
main cathode electrodes respectively connected to corresponding light emitting devices; and
a shield electrode between adjacent main cathode electrodes, the shield electrode being separated from the main cathode electrodes and electrically isolated from the main cathode electrodes, and
each of the light emitting devices is connected to any one of the first electrodes.

2. The display apparatus of claim 1, wherein a main cathode electrode is connected to a main light emitting device and a redundancy light emitting device included in a sub-pixel.

3. The display apparatus of claim 1, wherein at least two second electrodes connected to any one pixel driving circuit are used as one touch electrode.

4. The display apparatus of claim 3, wherein each of the at least two second electrodes extends along a first direction of the substrate, and
wherein the at least two second electrodes are provided along a second direction different from the first direction.

5. The display apparatus of claim 4, wherein when a cathode voltage is supplied to any one of the at least two second electrodes, light is output from light emitting devices connected to a second electrode to which the cathode voltage is supplied.

6. The display apparatus of claim 4, wherein a touch driving signal is concurrently supplied to the at least two second electrodes when the at least two second electrodes are used as one touch electrode.

7. The display apparatus of claim 1, wherein the main cathode electrodes are electrically connected to the light emitting devices, and
wherein the shield electrode is electrically isolated from the light emitting devices.

8. The display apparatus of claim 1, wherein a main cathode electrode is provided in a form of an island in an area corresponding to a light emitting device, and the shield electrode is provided outside the main cathode electrode.

9. The display apparatus of claim 1, wherein the shield electrode extends along a first direction of the substrate,
a through hole through which the light emitting device is exposed is provided in an area, which corresponds to a light emitting device, of the shield electrodes, and
the main cathode electrode is provided in a form of an island in the through hole.

10. The display apparatus of claim 1, wherein during a display period when an image is displayed, a cathode voltage is supplied to the main cathode electrodes and a shield voltage different from the cathode voltage is supplied to the shield electrode, and
during a touch period in which a touch is sensed, a touch driving signal is supplied to the main cathode electrodes and the shield electrode.

11. The display apparatus of claim 1, wherein each of the main cathode electrodes is connected to a main cathode electrode line through a main contact electrode, and
wherein the shield electrode is connected to a shield electrode line through at least one shield contact electrode.

12. The display apparatus of claim 11, wherein the main cathode electrode line and the shield electrode line are connected to a pixel driving circuit.

13. The display apparatus of claim 11, wherein during a display period when an image is displayed, a cathode voltage is supplied from the pixel driving circuit to a main cathode electrode through the main cathode electrode line and a shield voltage different from the cathode voltage is supplied from the pixel driving circuit to the shield electrode through the shield electrode line, and
during a touch period in which a touch is sensed, a touch driving signal is supplied from the pixel driving circuit to the main cathode electrode and the shield electrode through the main cathode electrode line and the shield electrode line.

14. The display apparatus of claim 1, wherein a separation area in which the main cathode electrode and the shield electrode are spaced apart from each other is provided outside the main cathode electrode.

15. The display apparatus of claim 14, wherein the separation area surrounds an outside of the main cathode electrode in a ring shape.

16. The display apparatus of claim 1, wherein the main cathode electrodes are spaced apart from each other with the shield electrode interposed therebetween in a non-overlapping configuration.

17. The display apparatus of claim 1, wherein each of the light emitting devices is connected to any one of the main cathode electrodes.
